(19) United States
(12) Patent Application Publication
(10) Pub. No.: US 2021/0281021 A1
(43) Pub. Date: Sep. 9, 2021

(54) ELECTRICAL CABLE COUPLER WITH POWER INDICATOR

(71) Applicant: 3M INNOVATIVE PROPERTIES COMPANY, St. Paul, MN (US)

(72) Inventors: Claudio A. Castro, Villa Alemana (CL); Martin J. Vos, St. Paul, MN (US); Javier J. Castro, Ñuñoa (CL); Jaylon D. Loyd, Austin, TX (US); Erik A. Aho, New Richmond, WI (US)

(21) Appl. No.: 16/623,231

(22) PCT Filed: Jun. 22, 2018
(86) PCT No.: PCT/IB2018/054636

§ 371 Date: Dec. 16, 2019

Related U.S. Application Data
(60) Provisional application No. 62/526,490, filed on Jun. 29, 2017.

(51) Int. Cl. H01R 13/717; G01R 19/165; H01R 13/66

(52) U.S. Cl. CPC H01R 13/7175; H01R 13/6683; H01R 13/7172; G01R 19/16523

(57) ABSTRACT

Devices, systems, and techniques are described for providing an indication of the presence of an electrical voltage potential at one or more electrical conductors and/or electrical terminals received in an electrical coupler. Examples of electrical couplers include an illumination coupling comprising a front flange, a rear flange, and an illumination channel extending between the front flange and the rear flange and configured to encircle a portion of the electrical coupler. A plurality of illumination devices positioned at least partially within the illumination channel are configured to provide visible light emissions when illuminated that are indicative of the presence of an electrical voltage potential on at least one of the one or more electrical conductors and/or electrical terminals received within the electrical coupler.

### TECHNICAL FIELD

The disclosure relates to electrical couplers, and more particularly, devices and methods for electrical couplers that include an indication of the presence of electrical voltage potential(s) within the electrical coupler.

### BACKGROUND

In various industrial environments and other environments where equipment is being operated, such as in mining operations, many devices may be employed that require electrical power be provided to the device by a wired power connection. These wired connections often take the form of an electrical cable that may include multiple individual electrical conductors insulated from one another, and provided together within a protective outer sheathing, which is normally flexible and formed from an electrically insulative material.

Often, the individual pieces of equipment that require electrical power are also required to be mobile. For example, a piece of equipment being employed in a mining operation may require electric power to operate, and may also be required to be movable from one location to another. These requirements often dictate that the piece of equipment be coupled to an electrical power source through an electrical cable, thus providing both electrical power to the device while allowing the device to remain mobile, even during times when the electrical power is being provided to the device and/or the device is operating.

### SUMMARY

This disclosure is generally directed to devices, systems, and methods for providing indications at an electrical coupler, for example visual and/or audio indications, related to the presence of a voltage potential on one or more of the electrical conductors terminated within an electrical coupler. The electrical couplers may be configured to allow connection and disconnection of electrical cables that include the electrical conductors terminated within the electrical coupler from other electrical cables, and/or from other devices such as power sources and devices to be powered by electrical power provided through the electrical cables.

Examples of electrical couplers described in this disclosure include an illumination coupling comprising a front flange, a rear flange, and an illumination channel extending between the front flange and the rear flange, and configured to encircle a portion of the electrical coupler. A plurality of illumination devices positioned at least partially within the illumination channel are configured to illuminate to provide visible light emissions when they are indicative of the presence of an electrical voltage potential on at least one of the one or more electrical conductors and/or electrical terminals that may be received, secured, and/or terminated within the electrical coupler.

Other examples of electrical couplers described in this disclosure include electrical couplers having a first ring and a second ring, each ring encircling the main body of the electrical coupler at a different position along the main body and spaced apart to form an illumination channel that also encircles a portion of the outer perimeter of the main body. A plurality of illumination devices may be positioned at least partially within the illumination channel formed in the space between the two rings, wherein the illumination devices are configured to illuminate to provide visible light emissions when illuminated that are indicative of the presence of an electrical voltage potential on at least one of the one or more electrical conductors and/or electrical terminals received, secured, and/or terminated within the electrical coupler.

Various electrical circuits are described that allow for sensing the presence of a voltage potential at one or more of the electrical conductors and/or electrical terminals that may be received, secured, and/or terminated within the electrical coupler, and to control the illumination of the illumination devices that are located within the illumination channels of the electrical coupler to provide an indication of the presence of a voltage potential or voltage potential at the one or more electrical conductors and/or electrical terminals.

In one aspect, the disclosure is directed to a device comprising: an illumination coupling comprising a front flange configured to be coupled to a front portion of an electrical coupler, a rear flange configured to be coupled to a main body of the electrical coupler, and an illumination channel extending between the front flange and the rear flange and configured to encircle a portion of the main body of the electrical coupler; a plurality of illumination devices positioned at least partially within the illumination channel and configured illuminate to provide visible light emissions when illuminated; and one or more electrical circuits electrically coupled to the plurality of illumination devices, each of the one or more electrical circuits configured to detect the presence of an electrical voltage on one or more electrical conductors or terminals received within the electrical coupler, and to control the illumination of the plurality of illumination devices based on the detected presence of the electrical voltage potential on at least one of the one or more electrical conductors or terminals.

In another aspect, the disclosure is directed to a device comprising: an electrical coupler configured to receive and to secure one end portion of one or more electrical conductors configured to carry electrical power, the electrical coupler comprising a main body and a front portion mechanically coupled to the main body; a first ring having an interior surface, side walls, and an outer surface, the interior surface of the first ring having a shape and having dimensions to allow the first ring to be encircle the main body at a first position along the main body; a second ring having an interior surface, side walls, and an outer surface, the interior surface of the second ring having a shape and having dimensions that allow the second ring to encircle the main body at a second position along the main body that is spaced apart from the first position relative to a longitudinal axis of the electrical coupler to provide an illumination channel encircling the portion of the main body between the first ring and the second ring; a plurality of illumination devices positioned at least partially within the illumination channel and configured to provide visible light emissions when illuminated; and one or more electrical circuits electrically coupled to the plurality of illumination devices, each of the one or more electrical circuits configured to detect the presence of an electrical voltage on one or more electrical conductors or terminals received within the electrical coupler, and to control the illumination of the plurality of illumination devices based on the detected presence of the electrical voltage potential on at least one of the one or more electrical conductors.

In another aspect, the disclosure is directed to a method comprising: sensing, by a sensor circuit, a voltage potential on one or more electrical conductors at a portion of each of the one or more electrical conductors that is received within an electrical coupler; and controlling, by electrical circuits, illumination of a plurality of illumination devices based on a sensed voltage potential on the one or more electrical conductors, wherein the one or more illumination devices are arranged around the outside perimeter of the electrical coupler and provide an illumination comprising visible light that is viewable from all angle around the outside of the electrical coupler when a minimum level voltage potential is sensed on at least one of the one or more electrical conductors.

The details of one or more examples are set forth in the accompanying drawings and the description below. Other features, objects, and advantages will be apparent from the description and drawings, and from the claims.

### BRIEF DESCRIPTION OF DRAWINGS

FIG. 1 is a conceptual diagram illustrating an example system including electrical couplers in accordance with the devices and techniques described in this disclosure.

FIG. 2A illustrates a side view of an example electrical coupler including an illumination coupling in accordance with the devices and techniques described in this disclosure.

FIG. 2B illustrates a side view of another example of an electrical coupler including an illumination channel in accordance with the devices and techniques described in this disclosure.

FIG. 3A illustrates a side view of an example electrical coupler in accordance with the devices and techniques described in this disclosure.

FIG. 3B illustrates a perspective view of the example electrical coupler of FIG. 3A.

FIG. 3C illustrates another perspective view of the example electrical coupler of FIG. 3A.

FIG. 3D illustrates an exploded view of an example electrical coupler in accordance with the devices and techniques described in this disclosure.

FIG. 4 illustrates an electrical schematic of an example electrical voltage detection and illumination circuit in accordance with the devices and techniques described in this disclosure.

FIG. 5A illustrates an electrical terminal including an example voltage sensing capacitor 144 in accordance with the devices and techniques described in this disclosure.

FIG. 5B illustrates a collet including an example voltage sensing capacitor in accordance with the devices and techniques described in this disclosure.

FIG. 6A illustrates a cutaway view of an example electrical coupler in accordance with various devices and techniques described in this disclosure.

FIG. 6B illustrates a sectional view of the example electrical coupler of FIG. 6A in accordance with the devices and techniques described in this disclosure.

FIG. 7 illustrates a schematic diagram of an example electrical circuit configured to sense and indicate a voltage potential in accordance with the devices and techniques described in this disclosure.

FIG. 8A illustrates an electrical schematic for an example sensing circuit in accordance with the devices and techniques described in this disclosure.

FIG. 8B illustrates a layout diagram of an example sensing circuit in accordance with the devices and techniques described in this disclosure.

FIG. 8C illustrates an example electrical circuit assembly in accordance with the devices and techniques described in this disclosure.

FIG. 9A illustrates a perspective view of an example illumination coupling in accordance with the devices and techniques described in this disclosure.

FIG. 9B illustrates a cutaway view of the example illumination coupling shown in FIG. 9A.

FIG. 9C illustrates a side view of the example illumination coupling shown in FIG. 9A.

FIG. 9D illustrates another side view of the example illumination coupling shown in FIG. 9A.

FIG. 10A illustrates an example illumination channel ring in accordance with the devices and techniques described in this disclosure.

FIG. 10B illustrates an example of a pair of illumination channel rings that are installed on a main body of an electrical coupler to form an illumination channel in accordance with the devices and techniques described in this disclosure.

FIG. 11 illustrates an example illumination insert 250 in accordance with the devices and techniques described in this disclosure.

FIG. 12 illustrates a flowchart of an example method in accordance with the devices and techniques described in this disclosure.

The drawings and the description provided herein illustrate and describe various examples of the inventive methods, devices, and systems of the present disclosure. However, the methods, devices, and systems of the present disclosure are not limited to the specific examples as illustrated and described herein, and other examples and variations of the methods, devices, and systems of the present disclosure, as would be understood by one of ordinary skill in the art, are contemplated as being within the scope of the present application.

### DETAILED DESCRIPTION

In general, the disclosure is directed to devices, systems, and methods for providing electrical couplers designed to allow connection and disconnection of electrical conductors configured to carry electrical power, such as individually insulated electrical conductors that may be provided together in an electrical cable. A first end portion the electrical conductors may be physically coupled to individual electrical terminals, such as a male pin or a female socket, that are provided in an electrical coupler that received and secures the first end portion of the electrical conductors. The second end of the electrical conductors may, for example, be coupled to a source of electrical power, or to another electrical coupler.

The electrical coupler may be configured to be received by or otherwise engage a second electrical coupler having a corresponding set of electrical terminals configured so that when the electrical coupler and the second electrical coupler are physically coupled together, the terminals within each electrical coupler provide an electrical connection between the terminals of the electrical coupler and the second electrical coupler. A second set of electrical conductors may be physically and electrically coupled to the corresponding terminals in the second electrical coupler. The ability to couple and uncouple (disconnect) the electrical coupler to and from the second electrical coupler provides a mechanism to electrically connect and disconnect the electrical conductors received in each of the electrical couplers to and from one another, for example to and from other electrical conductors in different cables, or for example to a power source or to a device to be powered by electrical power provide through the electrical conductors provided to the electrical coupler.

Examples of the electrical couplers described in this disclosure include devices configured to provide an indication, such as a visual and/or an audible indication, of the presence, and in some examples of the absence of an electrical voltage potential at one or more of the electrical conductors and/or electrical terminals that may be received, secured, and/or terminated within the electrical coupler. Various advantages with respect to safety and convenience provided by the electrical couplers having one or more indications, provided at the electrical coupler itself, and related to the presence and/or absence of a voltage potential or voltage potential present within the electrical coupler, will be discussed with respect to the figures as described below.

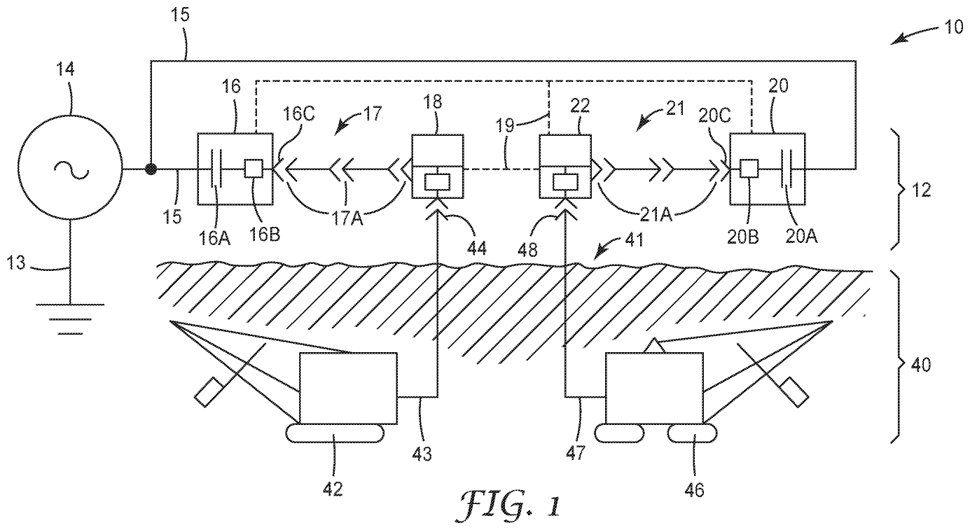

FIG. 1 is a conceptual diagram illustrating an example system 10 including electrical couplers in accordance with the devices and techniques described in this disclosure. System 10 includes an electrical distribution system 12 including an electrical power source 14, the electrical distribution system 12 arranged to provide electrical power to one or more electrically powered devices 40 operating in a production environment, such as a mining environment 41. System 10 is illustrative of an example of an electrical distribution system 12 and a mining environment 41 where the electrical couplers described in this disclosure, and any equivalents thereof, may be used. However, the electrical couplers, and any equivalents thereof, as described in this disclosure are not limited to use in an electrical distribution system 12 or for use in the mining environment 41 as depicted in FIG. 1, and may be utilized in any electrical system that utilized electrical couplers to allow for connection and disconnection of one or more electrical conductors according to the various examples of electrical couplers described herein.

As shown in FIG. 1, electrical power source 14 includes a power output 15 and a reference voltage 13 coupled to the power source. Power output 15 may include one or a plurality of electrical conductors configured to provide an electrical path for electrical power provided by power source 14 to be provided to one or more of the distribution devices included in electrical distribution system 12. The electrical power provided by power source 14 is not limited to any particular configuration of electrical power, and may include any configuration of electrical power that is required to provide the electrical power needed for proper operation of the electrically powered devices 40 included in or intended to operate in the mining environment 41. A configuration of electrical power as used herein refers to any arrangement of electrical power with respect to the voltage, maximum current, waveform, frequency, and/or number of and the arrangement of any different phases by which the electrical power is provided to the electrical conductors being connected through and disconnected by the electrical couplers described herein, and any equivalents thereof. For electrical power configurations providing an alternating current form of electrical power, voltage may be expressed as a peak voltage, a peak-to-peak voltage, or an average voltage, such as root-mean-square (RMS) voltage.

In some examples, the electrical power provided by power source 14 may be a commercially available electrical power having a voltage, several phases, a frequency, and/or an electrical configuration that is a same electrical configuration as provided by a commercial or governmental electrical utility provider. In some examples, the electrical power provided by power source 14 may include an electrical power configuration that is generated on-site, for example using an electrical generator that operates from another power source, such as another electrical power source, a chemical/fuel source, a wind or hydroelectrically generated power source, or some other source of energy. In some examples, the electrical power provided by power source 14 includes a configuration of electrical power that is transformed from one electrical power source, such as a commercial or governmentally provided electrical power source, to a different electrical power configuration with respect to voltage, number of phases, frequency, and/or an alternating current (AC) versus a direct current (DC) electrical power configuration.

In some examples, power source 14 provides a direct current (DC) electrical power supply to the electrical distribution system 12. Power source 14 may in some examples provide an alternating current (AC) electrical power supply to the electrical distribution system 12. In examples of power source 14 providing AC electrical power, the electrical configuration of the AC electrical power is not limited to any particular number of phases or phase configurations. In some examples, the AC electrical power may be a single-phase configuration. In other examples, the AC electrical power may be provided in a multi-phase electrical configuration, including a two-phase or a three-phase electrical configuration. In various examples, the electrical power provided by power source 14 may including a three-phase grounded or ungrounded delta configuration. In various examples, the electrical power provided by power source 14 may include a three-phase “Y” configuration that may be ungrounded or may be center-grounded.

The voltage level provided by power source 14 is not limited to any particular voltage or range of voltages. Voltages provided by power source 14 may be in a range of 5,000 to 25,000 V peak volts. A voltage provided by power source 14 may include three-phase electrical power having a root-mean-square (RMS) voltage of 15,000 VAC. In addition, the range of current levels that power source 14 is configured to provide is not limited to any particular range or maximum current levels. In some examples, power source 14 is configured to provide currents in the range of 250 to 800 amperes (A).

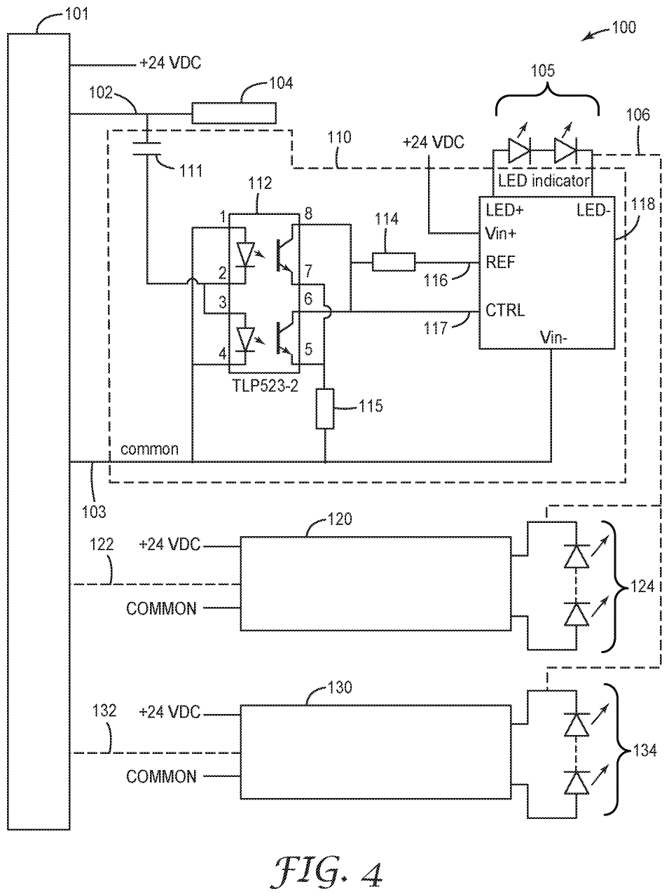

In addition, power source 14 may be configured to provide more than one source of electrical power, the more than one source of electrical power having different electrical power configurations. For example, power source 14 may configured to provide a first electrical power including a three-phase AC electrical power, for example to power the electrically powered devices 40, and a separated power source, such as a low-voltage DC electrical power that may be used to power illumination circuitry (not specifically shown in FIG. 1, but for example electrical circuits 110 and/or 118 as shown in FIG. 4) provided in one or more of the electrical couplers included in system 10.

As shown in FIG. 1, a first substation 16 is coupled to the power output 15 of power source 14, and is arranged to receive electrical power from power source 14. In some examples, first substation 16 includes switching circuits 16A that allows for connection and disconnection of the electrical power received from power source 14 with respect to the electrical outputs 16C provided from the first substation 16. First substation 16 may include electrical circuits 16B that performs one or more functions related to the electrical power received from power source 14 and as provided to the electrical outputs 16C. For example, electrical circuits 16B may include one or more protection devices, such as fuses, circuit breakers, and/or solid-state devices configured to provide over-voltage, over-current, and/or ground fault protection to the electrical outputs 16C provided by first substation 16. In various examples, electrical circuits 16B may include circuitry configured to provide one or more sources of electrical power having a different voltage, or a difference electrical configuration, such as a low voltage DC electrical power, relative to the power received from electrical power source 14. For example, electrical circuits 16B may include a DC power supply configured to rectify, filter, and provide as an output a low voltage DC electrical power, such as a +24 VDC electrical output, generated from a high or medium (5 to 25 kV) three-phase electrical power provided to first substation 16 by electrical power source 14.

First substation 16 may be located and positioned so that the first substation 16 does not need to be physically moved from one location or position to a different location or position, and thus may be coupled to power output 15 of power source 14 by electrical conductors that are provided in a fixed wiring enclosure, such as a wire trough or an electrical conduit. As shown in FIG. 1, the electrical connecting between the first substation 16 and power source 14 does not include an electrical coupler. However, in various examples, one or more electrical couplers may be provided between the first substation 16 and power source 14 to electrically couple first substation 16 to the power source 14, wherein one or more of these electrical couplers may include an electrical coupler according to any of the electrical couplers described in this disclosure, or any equivalents thereof.

In FIG. 1, a first breaker skid 18 is electrically coupled to the first substation 16 through electrical connection 17. The first breaker skid 18 is configured to receive electrical power from the first substation 16, and to distribute the received electrical power to loader 42. Loader 42 is an example of a piece of electrically powered equipment provided in mining environment 41 as part of system 10. Although only loader 42 is illustrated in FIG. 1 as being powered from first breaker skid 18, in some examples more than one piece of electrically powered equipment may be powered by the electrical power provided from the first breaker skid 18. First breaker skid 18 is electrically coupled to loader 42, and is configured to provide electrical power to operate the loader 42. In various examples, first breaker skid 18 may be a portable breaker skid, which is configured to be movable from one location to another relative to the first substation 16 and/or loader 42. The ability for the first breaker skid 18 to be portable allows for flexibility in locating and relocating the first breaker skid as the needs of operating the loader 42 and/or any other devices that may need to be powered from the first breaker skid evolve as part of the mining operations. As such, more permanent devices, such as wire troughs and/or rigid electrical conduits, may not be practical as a way to provide and protect the electrical connections used to electrically coupled the first breaker skid 18 with the first substation 16 and/or loader 42.

In order to facilitate the portability and flexibility that may be required with respect to the electrical connections made with the first breaker skid 18, flexible electrical cables, including a plurality of electrical conductors, and one or more electrical couplers provided at one or more locations along or at the end(s) of these electrical cables, may be provided to allow for connecting and disconnecting the electrical cables to and from these devices, and/or to and from other electrical cables. As shown in FIG. 1, electrical connection 17 includes a plurality of electrical couplers 17A coupling electrical connection 17 to the first substation 16 and to the first breaker skid 18. In addition, at least one electrical coupler 44 may be used to couple an electrical cable 43 to the first breaker skid 18, wherein electrical coupler 44 and cable 43 electrically couple the loader 42 to the first breaker skid 18.

As shown in FIG. 1, electrical couplers 17A include an electrical coupler coupling first substation 16 to a portion of electrical connection 17 formed for example from an electrical cable. Electrical couplers 17A also include a pair of electrical couplers coupling two portions of the electrical connection 17. Electrical couplers 17A also include an electrical coupler coupling a portion of electrical connection 17 to the first breaker skid 18. In various examples, one or more of the electrical couplers 17A and or electrical coupler 44 may comprise an electrical coupler including electrical circuits and an indication device arranged to provide an indication, such as a visual and/or an audio indication, that is indicative of the presence of an electrical voltage potential on one or more of the electrical conductors provided as part of the electrical connection 17 according to various examples of the electrical couplers describe in this disclosure, or any equivalents thereof. The electrical couplers 17A may be configured to couple one or more sets of electrical conductors configured to provide conductive pathways for electrical power at a voltage and using an electrical configuration or configurations provided by first substation 16 to the first breaker skid 18. In addition, electrical coupler 44 may be configured to couple one or more sets of electrical conductors provided in cable 43 that are configured to provide conductive pathways for electrical power at voltage(s) and using electrical configuration(s) arranged to couple electrical power provided by first breaker skid 18 to loader 42 through cable 43.

Examples of system 10 may further include a second substation 20 electrically coupled to the power output 15 of power source 14. Second substation 20 may receive power from power source 14, and may include switching circuits 20A that may be used to connect and to disconnect power received from power source 14 from the electrical outputs 20C of the second substation 20. Switching circuits 20A may be arranged to provide any of the features and function described above with respect to switching circuits 16A of the first substation 16, but with respect to the second substation 20, including generating and providing additional electrical power configurations from the electrical power provided by power source 14. Second substation 20 may include electrical circuits 20B that performs one or more functions related to the electrical power received from power source 14 and as provided to the electrical outputs 20C. For example, electrical circuits 20B may include one or more protection devices, such as fuses, circuit breakers, and/or solid-state devices configured to provide over-voltage, over-current, and/or ground fault protection to the electrical outputs 20C provided by second substation 20. Electrical circuits 20B may be arranged to provide any of the features and function described above with respect to electrical circuits 16B of the first substation 16, but with respect to the second substation 20.

In various examples, electrical circuits 20B may include circuitry configured to provide one or more sources of electrical power having a different voltage, or a difference electrical configuration, such as a low voltage DC electrical power, relative to the power received from electrical power source 14. For example, electrical circuits 20B may include a DC power supply configured to rectify, filter, and provide as an output a low voltage DC electrical power, such as a +24 VDC electrical output, generated from a high or medium (5 to 25 kV) three-phase electrical power provided to second substation 20 by electrical power source 14.

Second substation 20 may be located and positioned so that the second substation 20 does not need to be physically moved from one location or position to a different location or position, and thus may be coupled to power output 15 of power source 14 by electrical conductors that are provided in a fixed wiring enclosure, such as a wire trough or an electrical conduit. As shown in FIG. 1, the electrical connecting between the second substation 20 and power source 14 does not include an electrical coupler. However, in various examples, one or more electrical couplers may be provided between the second substation 20 and power source 14 to electrically couple second substation 20 to the power source 14, wherein one or more of these electrical couplers may include an electrical coupler according to any of the electrical couplers described in this disclosure, or any equivalents thereof.

In FIG. 1, a second breaker skid 22 is electrically coupled to the second substation 20 through electrical connection 21. The second breaker skid 22 is configured to receive electrical power from the second substation 20, and to distribute the received electrical power to stripper 46. Stripper 46 is an example of a piece of electrically powered equipment provided in mining environment 41 as part of system 10. Although only stripper 46 is illustrated in FIG. 1 as being powered from second breaker skid 22, in some examples more than one piece of electrically powered equipment may be powered by electrical power provided from the second breaker skid 22. Second breaker skid 22 is electrically coupled to stripper 46, and is configured to provide electrical power to operate the stripper 46. In various examples, second breaker skid 22 may be a portable breaker skid, which is configured to be movable from one location to another relative to the second substation 20 and/or stripper 46. The ability for the second breaker skid 22 to be portable allows for flexibility in locating and relocating the second breaker skid as the needs of operating the stripper 46 and/or any other devices that may need to be powered from the second breaker skid evolve as part of the mining operations. As such, more permanent devices, such as wire troughs and/or rigid electrical conduits, may not be practical as a way to provide and protect the electrical connections used to electrically coupled the second breaker skid 22 with the second substation 20 and/or stripper 46.

In order to facilitate the portability and flexibility that may be required with respect to the electrical connections made with the second breaker skid 22, flexible electrical cables, including a plurality of electrical conductors, and one or more electrical couplers provided at one or more locations along or at the end(s) of these electrical cables, may be provided to allow for connecting and disconnecting the electrical cables to and from these devices, and/or to other electrical cables. As shown in FIG. 1, electrical connection 21 includes a plurality of electrical couplers 21A coupling electrical connection 21 to the second substation 20 and to the second breaker skid 22. In addition, at least one electrical coupler 48 may be used to couple an electrical cable 47 to the second breaker skid 22, wherein electrical coupler 48 and cable 47 electrically couple the stripper 46 to the second breaker skid 22.

As shown in FIG. 1, electrical couplers 21A include an electrical coupler coupling second substation 20 to a portion of electrical connection 21 formed for example from an electrical cable. Electrical couplers 21A also include a pair of electrical couplers coupling two portions of the electrical connection 21. Electrical couplers 21A also include an electrical coupler coupling a portion of electrical connection 21 to the second breaker skid 22. In various examples, one or more of the electrical couplers 21A and/or coupler 48 may comprise an electrical coupler including electrical circuits and an indication device arranged to provide an indication, such as a visual and/or an audio indication, that is indicative of the presence of an electrical voltage potential on one or more of the electrical conductors provided as part of the electrical connection 21 according to various examples of the electrical couplers describe in this disclosure, or any equivalents thereof. The electrical couplers 21A may be configured to couple one or more sets of electrical conductors configured to provide conductive pathways for electrical power at a voltage and using an electrical configuration or configurations provided by second substation 20 to the second breaker skid 22. In addition, electrical coupler 48 may be configured to couple one or more sets of electrical conductors provided in cable 47 that are configured to provide conductive pathways for electrical power at voltage(s) and using electrical configuration(s) arranged to couple electrical power provided by second breaker skid 22 to stripper 46 through cable 47.

Although the first substation 16 and the second substation 20 are illustrated in FIG. 1 a having separate electrical connections coupling the power output 15 of power source 14 to these devices, in some examples the second substation 20 and/or the second breaker skid 22 may instead receive electrical power provided by power source 14 though the first substation 16 and/or the first breaker skid 18, as illustratively shown by dashed lines 19. These other electrical connections, illustratively shown in FIG. 1 as dashed lines 19, may also include electrical couplers with indication devices, such as visual and/or audio indications, including one or more of the various examples of electrical couplers described throughout this disclosure, and any equivalents thereof. Other arrangements for the devices and the distribution of electrical power in system 10 are possible, and are contemplated for use by the devices and methods illustratively shown and described with respect to system 10, which may include use of the electrical couplers as described though this disclosure, and any equivalents thereof.

The electrical couplers included in system 10 may be configured to provide an electrical connection between electrical conductors in a first electrical cable and other electrical conductors within different electrical cables, or between electrical conductors within an electrical cable and a device, such as the substations, the breaker skids, and the equipment illustrated and described with respect to system 10. In each example where an electrical coupler is utilized, the electrical coupler is constructed to provide adequate structure and as having electrical rating properties to connect, to carry, and to disconnect the electrical power intended to be carried by the electrical conductors being connected and disconnected by the electrical coupler. One or more of these electrical couplers may also incorporate electrical circuits and one or more indication devices configured to provide an indication of the presence of a voltage potential on one or more of the electrical conductors that are received, secured, and/or terminated within the electrical coupler.

Examples of indication devices may include devices provided as part of an electrical coupler that are configured to provide a visual and/or an audio indication of the presence of a voltage potential on at least one of the power electrical conductors that is received, secured, and/or terminated within the electrical coupler. Devices that provide a visual indication of the presence of a voltage potential within an electrical coupler include illumination devices, such as incandescent or gas lamps, and/or solid-state devices such as light-emitting-diodes (LEDs). Other forms of visual indications of the presence of a voltage potential within an electrical coupler may include a measurement device with an output display, such as a digital or analog meter, that indicates the presence of, and in some cases the measured value for the level of a voltage potential present within the electrical coupler. Devices that may provide an audio indication of the presence to a volt potential within an electrical coupler may include an audio alarm, such as a buzzer or a beeper, configured provide an audible tone or sound that is indicative of the presence and/or the absence of a voltage potential at an electrical coupler.

Sensing circuits used to detect the presence of a voltage potential at one or more of the power electrical conductors received, secured, and/or terminated at an electrical coupler may include sensing of electric or magnetic fields, for example using capacitive, inductive, or resistive sensors. In some examples, the power required to drive the indicative device, for example an illumination device such as LEDs, may be taken from the electrical power generating the voltage potential on the power electrical conductors within the electrical coupler. These systems may be referred to as “direct line driver” circuits because they do not require any outside power source to operate. In some of the systems used to provide the indication of a voltage potential on the power electrical conductor(s) within the electrical coupler, a separate power source, such as a low voltage DC power source, is used to power one or more devices used to operate the sensing circuits and/or the driver circuits used to control and power the indication device(s). These systems may be referred to as “indirect line driver” circuits because of the requirement for an additional power source to operate the circuit.

As would be understood by a general knowledge of the electrical distribution system 10 including the mining environment 41 or other environments where the electrical couplers illustrated in FIG. 1 might be utilized, that due to the distances between the devices being electrically coupled to one another, and other visual obstructions that may be located between these devices, an issue arises in that a user, such as a worker or maintenance personnel may not know, and may not easily be able to easily determine if one or more of the electrical couplers in the environment where they are working has energy on any of the electrical conductors that are received, secured, and/or terminated within the electrical coupler, as least by inspection of the electrical coupler alone. The examples of electrical couplers as described in this disclosure provide, at the electrical coupler itself, an indication of the presence of a voltage potential one or more of the power electrical conductors within the electrical coupler.

In the examples described in this disclosure, the presence of a voltage potential on one or more of the power electrical conductors within an electrical coupler may be indicated regardless of whether or not a current flow is occurring through the power electrical conductor(s) being monitored. Therefore, an indication of the presence of an electrical potential may be provided at the electrical coupler both when the electrical coupler is and when the electrical coupler is not coupled to a source of electrical voltage potential. Further, the indication devices described in this disclosure allow for a visual indication of the presence of a voltage potential to be provided around all sides of an electrical coupler, without the need for a user for example to pick up or otherwise physically manipulate the electrical coupler. The ability to potentially see the indication devices, and thus to be able to determine the status of the electrical coupler with respect to the presence or absence of the voltage potentials on the power electrical connectors within the electrical coupler from multiple angles around the electrical coupler provides an added level of safety to the user.

Due to the potential use of these electrical couplers in harsh operating environments, such as use of electrical couplers that are positioned so that they are laying on open ground in a mining environment, the electrical couplers may be damaged in a way that exposes a portion of an electrical conductor and/or an electrical terminal of the electrical coupler to unintended access through the damaged portion of the coupler. The ability to visually inspect a damaged electrical coupler to determine the presence or absence of a voltage potential within the electrical coupler without the need to touch or otherwise manipulate the electrical coupler provides a safety feature that may help avoid an accident and/or help prevent injuries to a user who is using the electrical coupler, who may be operating in the area of the electrical coupler, and/or when performing maintenance procedures on the electrical coupler. These and other benefits of the electrical couplers having the indications of the presence and/or absence of voltage potentials within the electrical coupler will be further described by the additional figures and the associated description of these figures as provided throughout this disclosure.

For the sake of illustration only, and not for the purpose of limitation in any manner, examples of electrical couplers described below may be directed to electrical couplers arranged to terminate electrical conductors intended to carry medium voltage three-phase AC electrical power. The term “medium voltage” may include peak voltages (relative to a reference voltage) in a range of 4 to 25 kV The term “three-phase” may refer to any arrangement of AC electrical power having a frequency and that includes three separate phases of an electrical potential provided on three separate electrical conductors, and arranged in a phase relationship to one another, such as in a “delta” or a “Y” configuration. The separate electrical conductors intended to carry the three-phase AC electrical power may be referred to as the power electrical conductors throughout this disclosure, and represent the electrical conductors, which may be provided for example in an electrical cable, and that each terminate at one end of the electrical conductors within one of the electrical couplers described though this disclosure. In addition to the power electrical conductors, an electrical conductor coupled to a reference voltage for the three-phase AC electrical power may also be included in the electrical cable, and may be referred to as a “common” conductor or as “ground”, and may also be terminated at one of the terminals provided within each of the electrical couplers. In addition, an electrical cable that is terminated at an example of the electrical couplers described throughout this disclosure may include one or more additional electrical conductors intended to carry other voltage potentials, such as a low voltage DC electrical power.

Electrical conductors and terminals provided in the electrical couplers described in this disclosure as the power electrical conductors may be configured to carry current in a range of 250 to 800 Amperes. As such, the electrical conductors and the terminals within the electrical couplers intended to carry the power electrical loads may be larger, for example in cross-sectional diameter, compared to the electrical conductors and terminals intended to carry for example the low voltage DC electrical power that may also be provide in a same cable as the medium voltage AC three-phase electrical power. Thus, a given electrical coupler may include terminals of various sizes to accommodate different levels of current carrying capacity for different electrical conductors provide within a same cable, and which may all be terminated in the electrical coupler, and which require being coupled to a mating terminal in a second coupler when coupled to the given electrical coupler.

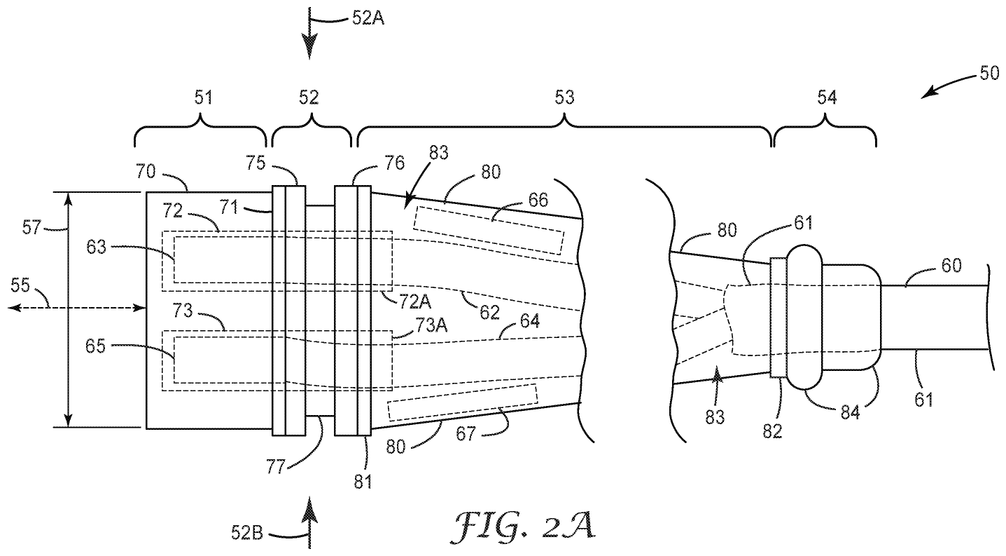

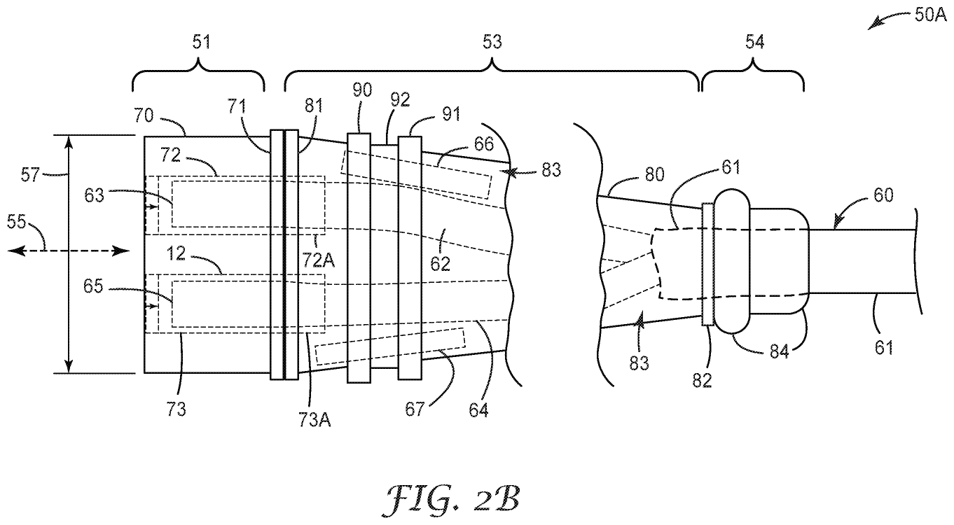

FIG. 2A illustrates a side view of an example electrical coupler 50 including an illumination coupling 52 in accordance with the devices and techniques described in this disclosure. Examples of electrical coupler 50 may be configured to provide an indication, such as a visual indication, of the presence and/or absence of a voltage potential on one or more of the power electrical conductors received, secured, and/or terminated within the electrical coupler. As shown in FIG. 2A, electrical coupler 50 includes a front portion 51, an illumination coupling 52, a main body 53, and a cable clamp 54. Cable clamp 54 is coupled to a rear flange 82 of the main body 53. A tapered housing 80 of the main body extends from the rear flange 82 to a front flange 81 of the main body 53, partially surrounding a hollow portion or space 83 within the main body 53, and increases in its cross-sectional dimension relative to a longitudinal axis 55 the electrical coupler 50 as the tapered housing extends from the rear flange 82 to the front flange 81. Illumination coupling 52 includes a rear flange 76 physically in contact with and mechanically coupled to the front flange 81 of the main body 53. A front flange 75 of the illumination coupling 52 is in contact with and is mechanically coupled to a rear flange 71 of the front portion 51. A portion of the illumination coupling 52 having a width dimension relative to the longitudinal axis 55 and provided between front flange 75 and rear flange 76, forms an illumination channel 77.

Front portion 51 includes a front portion housing 70 that extends from the rear flange 71 in a direction along the longitudinal axis 55 away from the illumination coupling 52. Front portion 51 also includes one or more terminal housings 72, 73 formed within the front portion and configured to provide a location for positioning electrical terminals within the front portion 51. A portion of terminal housings 72, 73 may extend rearward, illustratively show as extensions 72A, 73A, from the front portion into and/or through the interior space of the illumination coupling 52. The terminal housing 72, 73, and extensions 72A, 73A may perform various functions, such as insulating the terminals and exposed portions of the individual power electrical conductors from one and other within the electrical coupler, and to provide arc suppression when coupling and disconnecting electrical coupler 50 from a mating electrical coupler or a separate device. The positioning of these terminals, and the arrangement of front portion housing 70 of front portion 51, may be configured to allow front portion 51 to receive or to be received at a front portion of a mating electrical coupler for the purpose of allowing the terminals to be electrically coupled to, and at a later time electrically disconnected from, electrical terminal(s) in the mating coupler. The coupling and disconnection of the terminals within electrical coupler 50 may be made via access to these terminals provided by an opening 57 located across a front face of front portion 51, the opening 57 positioned at an opposite end of the front portion 51 relative to the rear flange 71 of the front portion.

The material or materials used to form the front portion 51, the illumination coupling 52, the main body 53, and the cable clamp 54 are not limited to any particular material or materials. In some examples of electrical coupler 50, one or more of the front portion 51, the illumination coupling 52, the main body 53, and/or the cable clamp 54 are formed, in whole or in part, of a metal or metallic material, such as cast aluminum. In some examples of electrical coupler 50, one or more of the front portion 51, the illumination coupling 52, the main body 53, and/or the cable clamp 54 are formed, in whole or in part, of plastic or resin material, such as polyurethane or epoxy. The coupling of the front portion 51, the illumination coupling 52, the main body 53, and/or the cable clamp 54 together to form the electrical coupler 50 as shown in FIG. 2A is not limited to use of any particular devices or fastening techniques. In some examples, one or more parts of the electrical coupler 50 including the front portion 51, the illumination coupling 52, the main body 53, and the cable clamp 54 may be coupled using fasteners, such as threaded machine screws or by using nuts and bolt type fasteners. In some examples, one or more parts of the electrical coupler 50 including the front portion 51, the illumination coupling 52, the main body 53, and the cable clamp 54 may be coupled together using an adhesive, such as an epoxy cement, or for examples by some form of coupling using a welding technique suitable to bond together the types of material used to form the part of the electrical coupler that are to be joined together.

As shown in FIG. 2A, the overall shape of the electrical coupler may be substantially a circular shaped in cross-section, at least with respect to the outmost surfaces of the electrical coupler, in a dimension perpendicular to the longitudinal axis 55 of the electrical coupler 50. However, the shape of the electrical coupler 50 is intended to be illustrative of an example of a shape of an electrical coupler, and other shapes, such as square, rectangular, and elliptical shapes may exist for example as the cross-sectional shape for the electrical coupler at one or more position along the longitudinal axis 55 of the electrical coupler, and are contemplated by the examples of electrical coupler described in this disclosure.

An electrical cable 60 including a plurality of electrical conductors 62, 64 provided within an outer covering 61 of cable 60, is illustrated having a portion of cable 60 received within electrical coupler 50. Each of the electrical conductors 62, 64 of cable 60 may also include an outer insulative cover that further protects the individual electrical conductors 62, 64, and also electrically insulates each electrical conductor from any other electrical conductor(s) provided within the outer layer 61 of cable 60. The number of electrical conductors included in cable 60 is not limited to two electrical conductors, or to a particular number of electrical conductors, and may include a number of electrical conductors required to provide one or more particular type(s) of electrical power, including electrical power provided as direct current (DC), alternating current (AC), and with one or multiple phases of AC electrical power.

For example, a cable 60 may include at least three power electrical conductors arranged to provide individual phases of a three-phase electrical system providing AC electrical power. Cable 60 may also include an electrical conductor designated to provide a reference voltage, such as a ground, for the electrical power relative to the electrical power provided on the one or more other power electrical conductors included in cable 60. In addition, different types of electrical power may be provided by different electrical conductors provided by cable 60. For example, in some instances a plurality of electrical conductor provided in cable 60 are arranged to provide individual phases of a three-phase AC electrical power, and one or more addition electrical conductors may be included in cable 60 to provide a separate DC electrical power. In various examples, these different electrical power configurations may share a common reference voltage conductor or “ground” within cable 60. In other instances, one or more of the electrical power configurations to be provided by the electrical conductors of cable 60 may be arranged to include different (separate) electrical conductors that are arranged to provide separate reference voltages, and completely separate electrical conductors for each of these different electrical power configurations, including separate reference voltage conductors for each different electrical power configuration, may be provided with cable 60.

As shown in FIG. 2A, cable 60 is received within an opening provided in cable clamp 54, and extends through a hollow portion or space 83 within the main body 53. Cable clamp 54 may be arranged so that after receiving cable 60 in the opening, a clamping mechanism, such as fasteners (not shown in FIG. 2A) coupling portions of the cable clamp to each other, may be actuated to exert a force on the outer layer 61 of cable 60 in order to secure in place the portion of the outer layer extending through the cable clamp.

Within the main body 53, the outer layer 61 of cable 60 ends, and the individual electrical conductors, illustratively shown as the first electrical conductor 62 and the second electrical conductor 64, extend through the hollow portion 83 of the main body 53 in the direction of illumination coupling 52. As described above, a third electrical conductor (not shown in FIG. 2A for clarity purposes) may also extend from the end portion of the outer layer 61 in a direction toward illumination coupling 52. Each of these power electrical conductors then extends in a direction through the center section within illumination coupling 52 and terminates at individual electrical terminals positioned within the terminal housings 72, 73, and a third terminal housing (not shown in FIG. 2A) of front portion 51. The termination of the electrical power conductors provides and electrical coupling between the individual electrical conductor and the individual terminal where the electrical conductor is terminated.

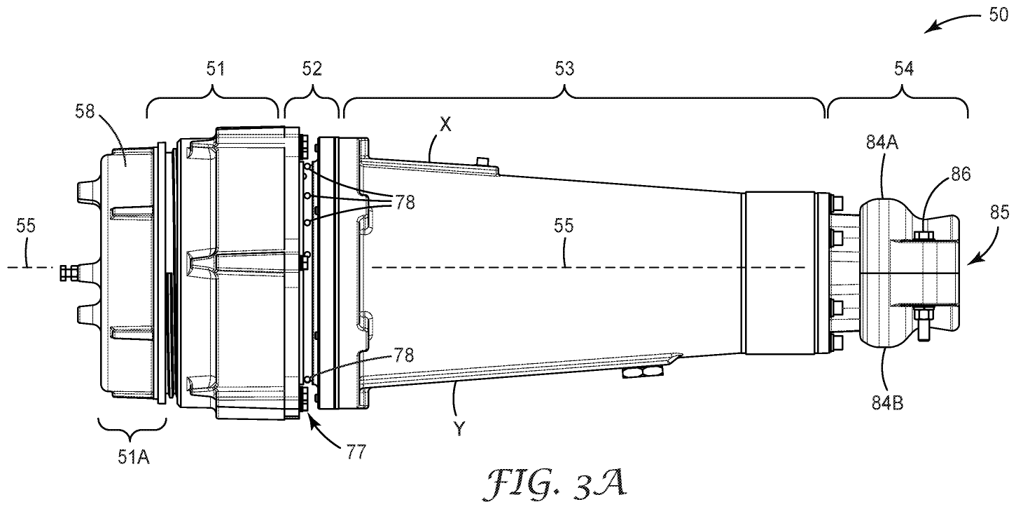

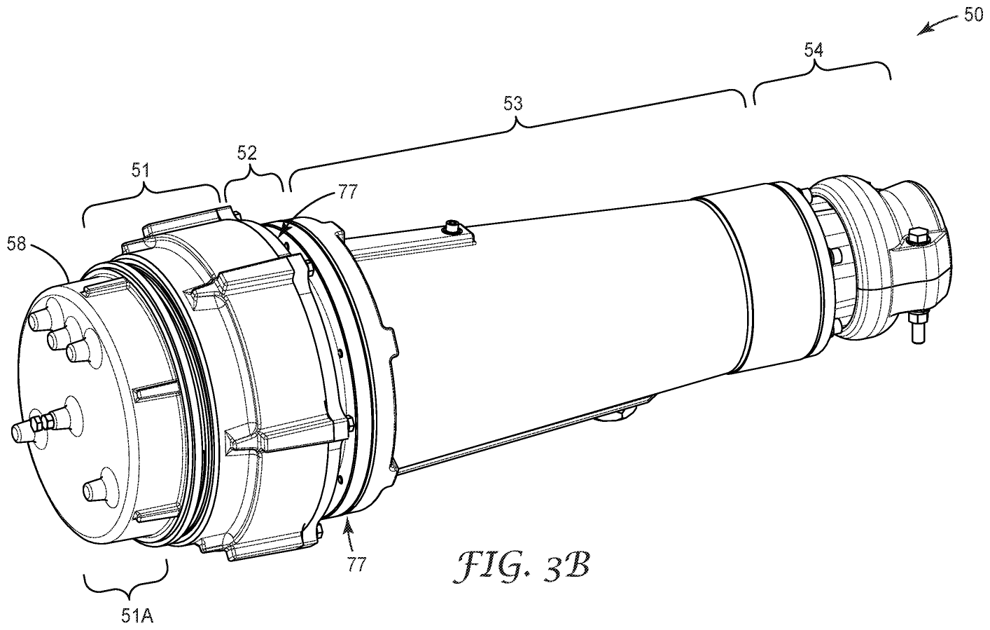

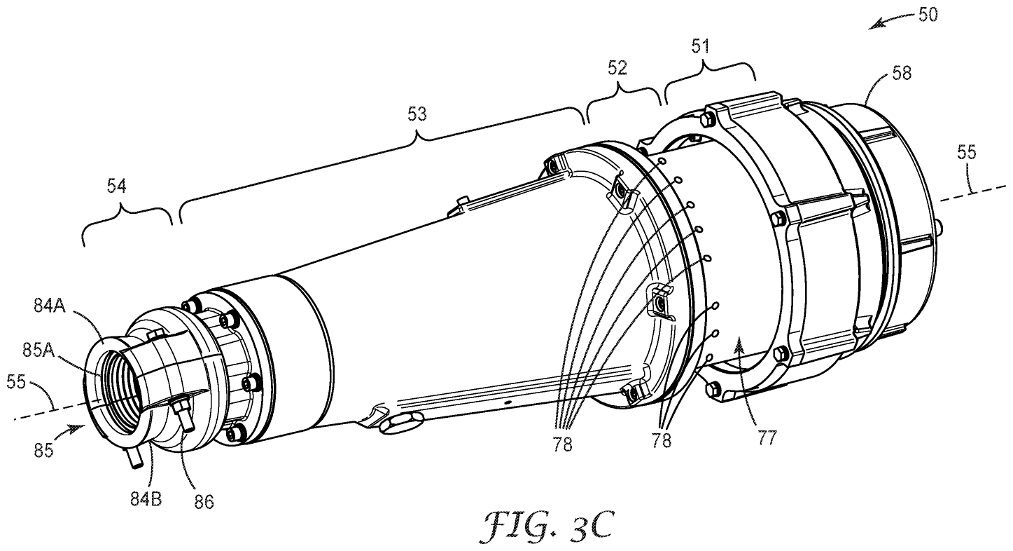

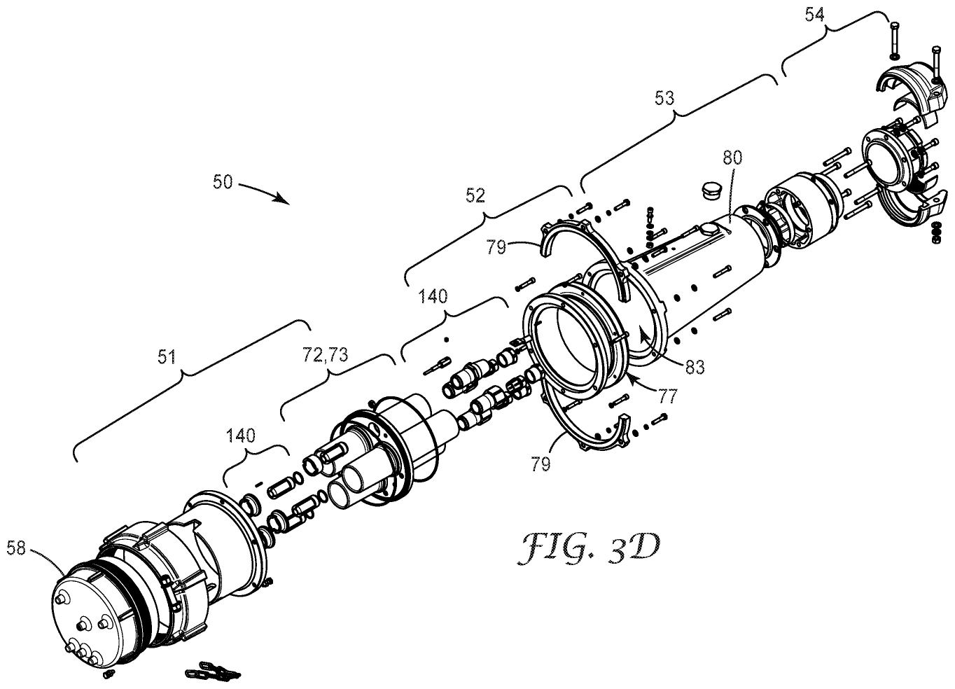

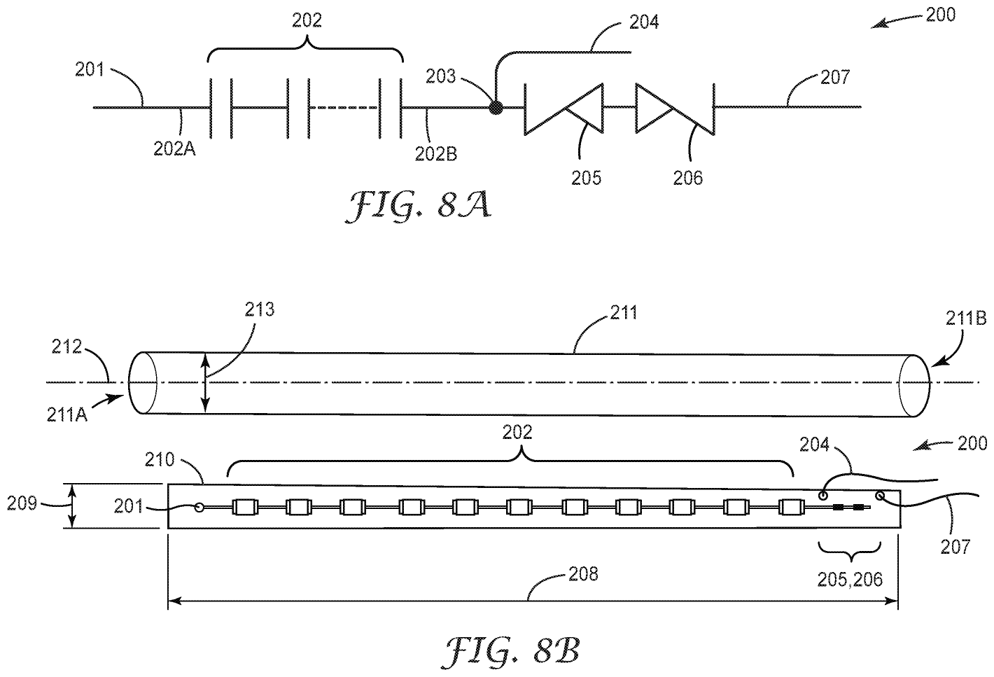

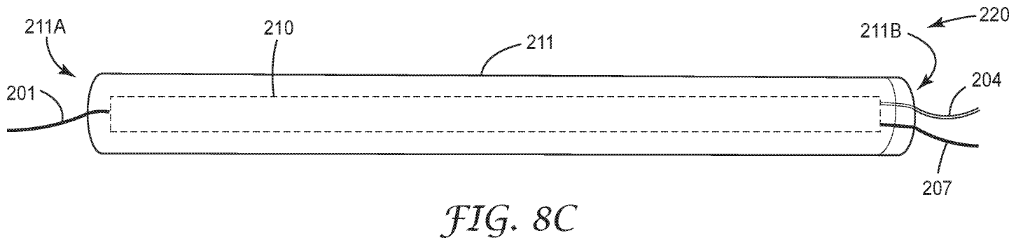

Each of the electrical conductors 62, 64 or the electrical terminals 63, 65 coupled to the ends of these electrical conductors, respectively, may be electrically coupled to one of the electrical circuits located within electrical coupler 50. For example, the first electrical conductor 62, or the first terminal 63 that is coupled to the first electrical conductor 62, may be electrically coupled to first electrical circuit 66. First electrical circuit 66 may include an input (not shown in FIG. 2A, but for example input 201 as shown in FIG. 8A) that is electrically coupled to the first electrical conductor 62 and/or first terminal 63. The input to the first electrical circuit 66 as shown in FIG. 2A provides, via the presence or absence of a voltage potential on the first electrical conductor 62 and/or the first terminal 63, an input signal to first electrical circuit 66. First electrical circuit 66 is also electrically coupled to one or more illumination devices (not shown in FIG. 2A, but for example illumination devices 78 as shown and described with respect to FIGS. 3A-3C). The illumination device(s) may be physically located at least partially or wholly within illumination channel 77 of the illumination coupling 52. As shown in FIG. 2A, the first electrical circuit 66 may be configured to control the illumination of these one or more illumination devices based on the presence or absence of a voltage potential on the first electrical conductor 62 and/or the first terminal 63.

For example, when a minimum level voltage potential is present on the first electrical conductor 62 and/or the first terminal 63, the voltage potential is coupled to the input of first electrical circuit 66, for example by an electrical conductor such as a metallic wire that is electrically coupled to the electrical conductor 62 or the first terminal 63. The first electrical circuit 66 is configured to receive the voltage potential, and to control the illumination of the one or more illumination devices coupled to the first electrical circuit based on the level of the voltage received at the input to the first electrical circuit.

When no voltage, or a voltage potential that is below the minimum level voltage potential is present on the first electrical conductor 62 and/or the first terminal 63, first electrical circuit 66 may not provide an electrical power output that would illuminate the one or more illumination devices coupled to the first electrical circuit 66, and thus the one or more illumination devices may be in an “OFF” state, that is, not emitting any visible light. When a voltage potential that is at or above the minimum voltage potential level is present on the first electrical conductor 62 and/or first terminal 63, that voltage potential may be electrically coupled to and received at the input to the first electrical circuit 66. When this minimum level voltage potential is received by first electrical circuit 66, the first electrical circuit 66 may be configured to provide an electrical power output to the one or more illumination devices coupled to the first electrical circuit. When electrical power output is provided to these illumination devices, the illumination devices are configured to illuminate, e.g., operate in a “ON” state, and emit a visible light as an indication of the presence of the voltage potential at the first electrical conductor 62 and/or first terminal 63.

The presence or absence of emitted visible light from the illumination devices coupled to the first electronic circuit 66 provides an indication of whether a minimum level voltage potential is present on the first electrical conductor 62 and/or the first terminal 63. Because the first electrical circuit 66 is arranged to control the illumination of the illumination devices by sensing a voltage potential, there is no requirement that an actual current flow through the first electrical conductor 62 and/or terminal 63 be present in order to make the determination as to whether or not the minimum level voltage potential is present at the first electrical conductor 62 and/or the first terminal 63. This feature of the first electrical circuit 66 allows for control of the illumination devices, and thus ability to provide the visual indication provided by these illumination devices, whenever a minimum level voltage potential is present on the electrical conductor 62 and/or terminal 63, regardless of whether the electrical coupler 50 is coupled to another device or another electrical coupler that is providing an addition path for actual current flow through electrical coupler 50.

In various examples, the first electrical circuit 66 may be physical located within the hollow space 83 provided within main body 53, as illustrated in FIG. 2A. However, the location of first electrical circuit 66 is not limited to any particular location within electrical coupler 50, and may be for example incorporated into the electrical coupler 50 within the area surrounded by illumination coupling 52. In some examples, the monitoring of an indication of a voltage potential may only be provided on one electrical conductor, such as electrical conductor 62 of electrical coupler 50, even when more than one phase of electrical power is provided on separate power electrical conductors and is received and potentially powered with the electrical coupler.

In some examples, the presence or absence of a minimum level voltage potential may be indicated by illumination devices for more than one of the power electrical conductors received within electrical coupler 50. For example, as shown in FIG. 2A, electrical coupler 50 includes a second electrical circuit 67 located within the hollow space 83 within the main body 53 of the electrical coupler 50. Second electrical circuit 67 may include an input (not shown in FIG. 2A, but for example input 201 as shown and described with respect to FIG. 8A) that is electrically coupled to the second electrical conductor 64 and/or the second terminal 65 of FIG. 2A. The input to the second electrical circuit 67 provides, via the presence or absence of a voltage potential on the second electrical conductor 64 and/or the second terminal 65, an input signal to the second electrical circuit 67. Second electrical circuit 67 is also electrically coupled to one or more illumination devices (not shown in FIG. 2A, but for example illumination devices 78 as illustrated and described with respect to FIGS. 3A-3C). The illumination device(s) may be physically located at least partially or wholly within illumination channel 77 of the illumination coupling 52. The second electrical circuit 67 is configured to control the illumination of these one or more illumination devices based on the presence or absence of a voltage potential on the second electrical conductor 64 and/or the second terminal 65.

For example, when a minimum level voltage potential is present one the second electrical conductor 64 and/or the second terminal 65, the voltage potential is coupled to the input of second electrical circuit 67, for example by an electrical conductor such as a metallic wire electrically coupled to the second electrical conductor 64 or to the second terminal 65. The second electrical circuit 67 is configured to receive the voltage potential, and to control the illumination of the one or more illumination devices coupled to the second electrical circuit 67 based on the level of the voltage received at the input to the second electrical circuit. For example, when no voltage, or a voltage potential that is below the minimum level voltage potential is present on the second electrical conductor 64 and/or the second terminal 65, second electrical circuit 67 may not provide an electrical power output that would illuminate the one or more illumination devices coupled to the second electrical circuit 67, and thus these one or more illumination devices may be in an “OFF” state, that is, not emitting any visible light.

When a voltage potential that is at or above the minimum voltage potential level is present on the second electrical conductor 64 and/or second terminal 65, the voltage potential may be electrically coupled to and received at the input to the second electrical circuit 67. When this minimum level voltage potential is received by second electrical circuit 67, the second electrical circuit 67 may be configured to provide an electrical power output to the one or more illumination devices coupled to the second electrical circuit. When an electrical power output is provided to these illumination devices, the illumination devices are configured to illuminate, e.g., operate in a “ON” state, and emit a visible light as an indication of the presence of the voltage potential at the second electrical conductor 64 and/or second terminal 65.

While not specifically shown in FIG. 2A, it would be understood that a third electrical conductor coupled to a third terminal may be included as part of cable 60, as part of a set of power electrical conductors arranged to connect and disconnect a three-phase AC electrical power configuration intended to be carried by cable 60. In various examples, a third electrical circuit (not specifically shown in FIG. 2A), may be provided within electrical coupler 50, the third electrical circuit arranged in a manner similar to that described above for the first electrical circuit 66 and the second electrical circuit 67, to receive an input related to the presence or absence of a minimum level voltage potential on the third power electrical conductor and/or the third terminal, and to control the illumination of one or more illumination devices located at least partially or wholly within the illumination channel 77 based on the presence or absence of the minimum level voltage potential at the third electrical conductor and/or the third terminal. This third electrical circuit may be physical located within the hallow space 83 of the main body 53 in a similar manner as illustrated in FIG. 2A with respect to the first electrical circuit 66 and second electrical circuit 67, or may be locate at some other position within electrical coupler 50, such as within an area surrounded by illumination coupling 52.

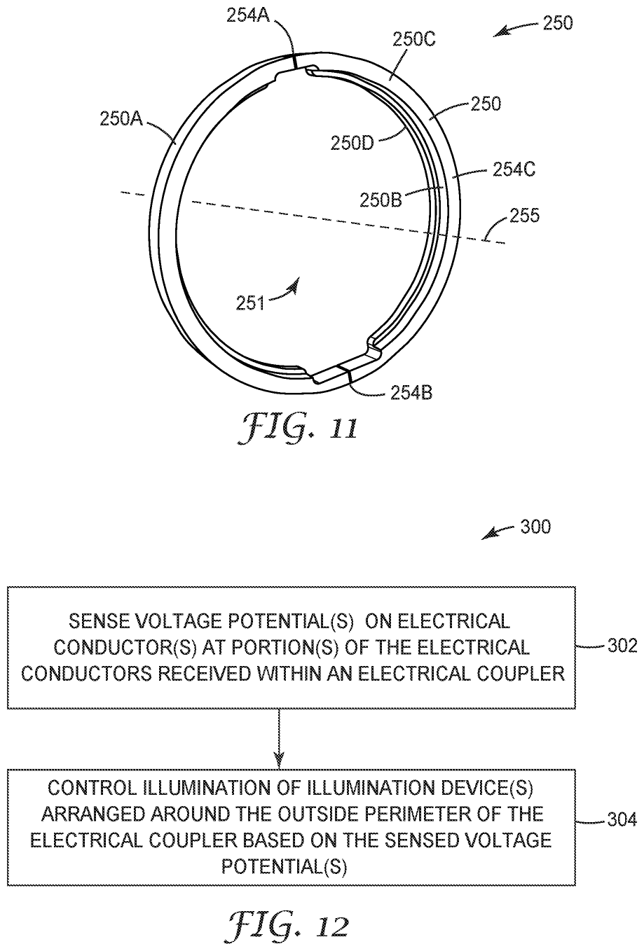

In various examples, the illumination channel includes a covering or fill material provided within illumination channel 77 and for example covering any of the illumination devices that may be partially or wholly located within the illumination channel. Any covering or fill provided within the illumination channel 77 may be provided to further protect the illumination devices located within the illumination channel while still allowing the light emitted by the illumination devices to be visible outside the illumination channel. In various examples, the covering or fill material may also act to aid in the distribution of the light being emitted from the illumination devices, and further described for example with respect to the illumination insert illustrated and described with respect to FIG. 11.

Referring again to FIG. 2A, the illumination devices controlled by any of the electrical circuits 66, 67, or a third electrical circuit may be arranged around the perimeter of the electrical coupler 50 formed by the illumination channel 77 so that at least one of the illumination devices controlled by each one of the electrical circuits would be visible from at least any angle perpendicular to the illumination channel surrounding the electrical coupler 50. For example, at least one illumination device controlled by each of the electrical circuits 66, 67, and a third electrical circuit controlling the illumination of illumination devices within illumination channel 77 would be visible when looking at the illumination channel 77 from an angle (e.g., a side view) as shown in FIG. 2A, when looking at the illumination channel 77 from a side of the electrical coupler opposite the side view shown in FIG. 2A, and when looking at the illumination channel 77 from a top side (indicated by the direction of arrow 52A), or a bottom side (indicated by the direction of arrow 52B) of the electrical coupler as shown in FIG. 2A. This feature of full visibility of the illumination devices providing a visual indication for all phases of the power electrical conductors from at least any angle of view perpendicular to the longitudinal axis of the electrical coupler, and other viewing angles of elevation relative to the illumination channel, adds a level of safety for person inspecting and/or handling the electrical coupler 50 in that the indication of the presence of a voltage potential within the electrical coupler on any of the power electrical conductors may be visually determined without the need to touch or physically manipulate the coupler in order to expose a viewing angle of the illumination devices. This feature may be helpful for example when the electrical coupler is not visible on a certain side of the electrical coupler without be physically manipulated, such as when the coupler may be lying on the ground, and thus a bottom side and/or portions of the sides of the electrical coupler, and thus portions of the illumination channel 77, are not readily visible.

Further, the ability to provide the visual indication regarding the presence and/or absence of a voltage potential within the electrical couple, for example even when the electrical coupler is not physically coupled to another device or to another electrical coupler providing an current path through the electrical coupler, provides an added level of safety for persons operating, inspecting, and coupling/uncoupling the electrical coupler 50 by providing a visual indication of the presence of a voltage potential at one or more of the electrical conductors received within the electrical coupler regardless of whether the electrical couple is coupled or is not coupled to another device at the front portion 51 of the electrical coupler. Further, the individual indications of which phases of the electrical conductors within the electrical coupler 50 may be at a voltage potential and which may not be at a voltage potential also provides a troubleshooting tool that may be useful in locating and repairing disconnections, open or short circuits, or other electrical issues with individual electrical conductors within an electrical cable or within the electrical coupler where the electrical conductors of the electrical cable have been received.

FIG. 2B illustrates a side view of another example of an electrical coupler 50A including an illumination channel 92 in accordance with the devices and techniques described in this disclosure. Examples of electrical coupler 50A may be configured to provide an indication, such as a visual indication, of the presence and/or absence of a voltage potential on one or more of the power electrical conductors received, secured, and/or terminated within the electrical coupler. As shown in FIG. 2B, electrical coupler 50A includes a front portion 51, a main body 53, and a cable clamp 54. Electrical coupler 50A includes electrical cable 60 including electrical conductors 62, 64 provided in cable 60 being received and terminated at terminals 63, 65, respectively within the terminal housings 72, 73 of front portion 51. Electrical coupler 50A includes first electrical circuit 66 electrically coupled to the first conductor 62 and/or first terminal 63, and configured to control one or more illumination devices (not shown in FIG. 2B), to provide an indication of the presence or absence of a minimum level of voltage potential at the first conductor 62 and/or first terminal 63 in a similar manner as described above with respect to FIG. 2A.

As also shown in FIG. 2B, electrical coupler 50A includes second electrical circuit 67 electrically coupled to the second electrical conductor 64 and/or second terminal 65, and configured to control one or more illumination devices (not shown in FIG. 2B) to provide an indication of the presence or absence of a minimum level of voltage potential at the second electrical conductor 64 and/or second terminal 65 in a similar manner as describe above with respect to FIG. 2A. Electrical coupler 50A may also include a third electrical circuit (not shown in FIG. 2B for the sake of clarity) that is electrically coupled to a third power electrical conductor provided in cable 60, the third electrical circuit arranged to receive an input corresponding to the presence or absence of a voltage potential on the third conductor and/or third terminal, and to control the illumination of one or more illumination devices (not shown in FIG. 2B) coupled to the third electrical circuit in a similar manner as described above with respect to the third electrical circuit in FIG. 2A.

The electrical coupler 50A as illustrated in FIG. 2B differs from the electrical coupler 50 as illustrated and described with respect to FIG. 2A in that electrical coupler 50A does not include the illumination coupling 52, and instead has the front flange 81 of the main body 53 that is physically coupled directly to the rear flange 71 of the front portion 51 of electrical coupler 50A. As such, each of the electrical circuits 66, 67 and a third electrical circuit, if present in coupler 50A, may be located in the hollow space 83 provided within main body 53.

As described above, electrical coupler 50A does not include the illumination coupling 53, and thus also does not include the illumination channel 77 provided as part of the illumination coupling. Instead, an illumination channel 92 is formed around the perimeter of a portion of the main body 53 of the electrical coupler 50A between a first ring 90 and a second ring 91. First ring 90 and second ring 91 may be positioned apart from each other relative to the longitudinal axis 55 of the electrical coupler 50A, each ring surrounding a portion of the tapered housing 80 to create a protected illumination channel 92 in a space between the rings. The illumination devices that are electrically coupled to the electrical circuits (e.g., electrical circuits 66, 67, and a third electrical circuit not shown in FIG. 2B), provide with electrical coupler 50A may be physically located within the illumination channel 92, and arranged so that visible light emitted from the illumination devices when the illumination devices are powered to an “ON” state may be visible from all angles perpendicular to the longitudinal axis 55 surrounding the electrical coupler 50A in a similar manner as described above with respect to the illumination devices and the illumination channel 77 in FIG. 2A.

Rings 90 and 91 may including outer surfaces that extend beyond an outer surface of the illumination channel 92 relative to a distance from the longitudinal axis 55 in order to provide physical protection to the illumination devices, and any covering or fill material provide within illumination channel 92. Any covering or fill provided within in illumination channel 92 may be provided to further protect the illumination devices located within the illumination channel while still allowing the light emitted by the illumination devices to be visible outside the illumination channel 92. The spacing between rings 90 and 91 relative to longitudinal axis 55 forms the width of the illumination channel 92, and the side walls of rings 90 and 91 that face one another form the side wall, and thus a depth, of the illumination channel 92 perpendicular to the longitudinal axis 55 and encircling the entire perimeter of the main body 53 in the area defined as the width of the illumination channel 92 by the inside walls of rings 90 and 91 that face the illumination channel.

In a manner similar to that described above with respect to the electrical circuits 66, 67 and the illumination devices located in illumination channel 77 of electrical coupler 50, the electrical circuits 66, 67 and the illumination devices that may be located within illumination channel 92 may be configured to provide a visual indication of the presence or absence of a voltage potential on one or more of the electrical conductors and/or terminals the are received, secured, and/or terminated within electrical coupler 50A.

FIG. 3A illustrates a side view of an example electrical coupler 50 in accordance with the various devices and techniques described in this disclosure. In some examples, electrical coupler 50 as shown in FIG. 3A is an example of the electrical coupler 50 illustrated and described with respect to FIG. 2A. As shown in FIG. 3A, electrical coupler 50 includes front portion 51, illumination coupling 52, main body 53, and cable clamp 54, arranged in a similar manner relative to each other as described and illustrated with respect to FIG. 2A. As shown in FIG. 3A, electrical coupler 50 includes a cover 58 attached to front portion 51 in a position that provides protection to the terminals and the interior portions of the front portion 51 when electrical coupler 50 is not coupled to another electrical coupler. As illustrated in FIG. 3A, front portion 51 may include a threaded portion 51A that is configured to engage a threaded portion on an interior surface of the cover 58 to allow cover 58 to be secured in place covering the opening of the front portion 51.

As further illustrated in FIG. 3A, electrical coupler 50 includes illumination channel 77 that includes a plurality of illumination devices 78 located at least partially within the illumination channel 77. The illumination devices 78 are coupled to electrical circuits (not shown in FIG. 3, but for example electrical circuits 66, 67 shown and described with respect to FIG. 2A), that control illumination devices 78 so that illumination devices 78 provide a visual indication of whether an electrical voltage potential and/or electrical power is present at a portion of one or more of the electrical conductor and/or terminals received, secured, and/or terminated within electrical coupler 50. The electrical conductors may be provided as part of an electrical cable (not shown in FIG. 3A) wherein a portion of the electrical cable is received and secured by cable clamp 84, and extends into the main body 53 of the electrical coupler 50, wherein the electrical conductors included in the cable are terminated at one or more terminals positioned at least partially within the front portion 51 of the electrical coupler 50. In various examples, one or more of the terminals and/or the electrical conductors are electrically coupled to the electrical circuits that control the illumination devices 78. In some examples, the electrical circuits are configured to provide electrical power used to illuminate one or more of the illumination devices when an electrical voltage potential is present on one or more of the terminals and/or electrical conductors within the electrical coupler 50.

As shown in FIG. 3A, the illumination devices 78 may be provided in sets or groups distributed along the illumination channel 77 in a manner so that at least one of the sets or groups of illumination devices is visible from at least any angle of view of the illumination channel that is perpendicular to the longitudinal axis 55 of the electrical coupler. In addition, in examples where different ones of the illumination devices are controlled to indicate the presence and/or absence of a minimum level voltage potential for different electrical conductors within the electrical coupler 50 of FIG. 3A, each set or group of illumination devices may be configured to include at least one illumination device controlled to provide a visible indication of the presence or absence of a voltage potential on each one of the power electrical conductors provided within the electrical coupler. In this way, at least one illumination device configured to indicate the presence or absence of a voltage potential for each of the power electrical conductors received, secured, and/or terminated within the electrical coupler will be visible from at least any angle of the illumination channel that is perpendicular to the longitudinal axis 55 of the electrical coupler.

Additional details of the cable clamp 54 as shown in FIG. 3A include a first clamp portion 84A coupled to a second clamp portion 84B by one or more fastener 86, and forming an opening 85 arranged to receive and secure a portion of an electrical cable (not shown in FIG. 3A, but for example cable 60 shown in FIG. 2A) that may be inserted into the electrical coupler 50 through cable clamp 54. The first clamp portion 84A and the second clamp portion 84B are configured to expand apart from one another to allow a portion of an electrical cable to be received in opening 85, and then by using fastener(s) 86, to be drawn together to provide a clamping force on the portion of the electrical cable receive in the opening 85 to secure the portion of the electrical cable received within the electrical coupler 50.

FIG. 3B illustrates a perspective view of the electrical coupler 50 of FIG. 3A. FIG. 3B illustrates the electrical coupler 50 including front portion 51, illumination coupling 52, main body 53, and cable clamp 54. The perspective in FIG. 3B shows electrical coupler 50 looking toward the cover 58, and showing cover 58 coupled to the threaded portion 51A of front portion 51. A portion of the illumination coupling 52 and the illumination channel 77 are visible in the perspective view of FIG. 3B. As illustrated in FIG. 3B, a portion of the illumination channel 77, and thus illumination provided by the illumination devices included within the illumination channel, may be visible at angles of view that are not necessarily perpendicular to the longitudinal axis 55 of the electrical coupler 50, for example at an angle of view relative to the illumination channel 77 depicted by in FIG. 3B. This additional visibility may add another level of safety and convenience provided by the ability to visually determine the status of the electrical coupler 50 with respect to voltage potential(s) that may be present within the electrical coupler without having to necessarily view the electrical coupler 50 and/or the illumination channel 77 at a viewing angle perpendicular to the longitudinal axis of the electrical coupler.

FIG. 3C is another perspective view of the electrical coupler 50 of FIG. 3A. FIG. 3C illustrates the electrical coupler 50 including front portion 51, illumination coupling 52, main body 53, and cable clamp 54, viewing the electrical coupler looking toward the cable clamp 54. As shown in FIG. 3C, cable clamp 54 includes opening 85 that may include ridges 85A configured to further grip the outer layer of an electrical cable (not shown in FIG. 3C) that may be received in opening 85 in order to provide strain relieve to the received cable when the portion of cable outside the electrical coupler 50 is pulled on or bent in a direction away from the electrical coupler.

As also illustrated in FIG. 3C, one or more of the illumination devices 78 are visible in the illumination channel 77 of the illumination coupling 52. In various examples, illumination devices 78 include LED devices. In various examples, the illumination devices 78 extend at least partially or wholly within illumination channel 77, and may be covered by or enclosed within the illumination channel by a clear or translucent cover (not shown in FIG. 3B) that further protects the illumination devices while allowing any light emitted by the illumination devices to be visible outside the illumination channel 77. In various examples, sets or groups of illumination devices 78 may be spaced around the outside perimeter of the illumination coupling 52 and within the illumination channel 77 so that at least one illumination device associated with each of the electrical power conductors being monitored for the presence and/or absence of a voltage potential will be visible from at least any angle of the illumination channel surrounding the illumination channel that is perpendicular to the longitudinal axis 55 of the electrical coupler 50.

In various examples, one of the illumination devices 78 in each set or group of illumination devices is coupled to an electrical circuit arranged to control illumination of the illumination devices 78 in conjunction with the sensed voltage potential for one of the electrical conductors received within electrical coupler 50, wherein each of the sets or groups of illumination devices 78 includes at least one illumination device configured to be controlled to indicate the presence or absence of a voltage potential on each of the power electrical conductors received, secured, and/or terminated in the electrical coupler 50. As such, for at least each angle of view surrounding the illumination channel 77 perpendicular to longitudinal axis 55, at least one illumination device 78 providing an indication of the presence or absence of a voltage potential for each of the power electrical connectors is visible. In addition, visibility of the illumination of the illumination devices 78 provided in the illumination channel 77 may be possible at angles of view other than angles of view that are perpendicular to the longitudinal axis 55 of the electrical coupler, for example at an angle as provided by the angle illustrated in FIG. 3C. Such visibility can provide an added level of safety for users based on increased visibility of the illumination devices 78 for reasons described above.

FIG. 3D illustrates an exploded view of the example electrical coupler 50 according to the devices and techniques described in this disclosure. As show in FIG. 3D, coupler 50 includes cover 58, front portion 51, illumination coupling 52, main body 53, and cable clamp 54. Front portion 51 includes a set of terminals 140 configured to provide electrical connections with other terminals in a mating coupler (not shown in FIG. 3D) for each individual power electrical conductors received in the electrical coupler 50. Terminals 140 are configured to be positioned, individually, in one of the terminal housing 72, 73, shown in FIG. 3D. Terminals 140 may be electrically and physically coupled to the power electrical conductors provided in an electrical cable (not shown in FIG. 3D) having a portion of the electrical cable received and terminated within electrical coupler 50. In various examples, a sensing circuit or circuits, such as electrical circuits 66, 67 as illustrated and described with respect to FIGS. 2A and 2B, may be electrically coupled to one or more of terminals 140 illustrated in FIG. 3D to sense voltage potentials on these one or more terminals, and to control the illumination of illumination devices located within the illumination channel 77 of illumination coupling 52 to provide a visual indications regarding the presence or absence of a minimum voltage potential at one or more of terminals 140. These sensing circuits and/or electrical circuits may be physically located in the space 83 provided within the main body 53 of the electrical coupler 50.

In various examples, an illumination insert 79 may be provided that is configured to be inserted at least partially or wholly within the illumination channel 77, and to provide physical protection of the illumination devices that are located within the illumination channel 77. In various examples, illumination insert 79 functions as a light pipe to conduct light emitted by one or more of the illumination devices to other portions of, or around the entire perimeter portion of the illumination channel 77 to help provide a visual indication of the light being emitted by the illumination devices. Additional illustration and details regarding examples of the illumination insert 79 are provided with respect to FIG. 11 and the description associated with FIG. 11 provided below.

FIG. 4 illustrates an electrical schematic of an example electrical voltage detection and illumination circuit 100 in accordance with various devices and techniques described in this disclosure. As shown in FIG. 4, an electrical cable 101 includes at least one electrical conductor 102 configured to accept an electrical voltage and carry electrical current, and that is terminated at an electrical terminal 104 within an electrical coupler. Electrical circuit 110 is coupled to the electrical conductor 102, or in some instances to the electrical terminal 104, and to the reference voltage line 103 included in cable 101. Electrical circuit 110 is also electrically coupled to one or more illumination devices 105. Electrical circuit 110 in some examples is any of the electrical circuits located within a main body of the electrical coupler, such as electrical circuits 66 and 67 shown in FIGS. 2A and 2B, that is configured to sense voltage potentials and to control the illumination of one or more illumination devices based on the sensed voltage potential. As further described below, electrical circuit 110 may be configured to sense the presence of an electrical voltage potential on electrical conductor 102 and/or electrical terminal 104, and to control the illumination of at least the illumination devices 105 based on sensing the presence or absence of a minimum level voltage potential on electrical conductor 102 and/or terminal 104.

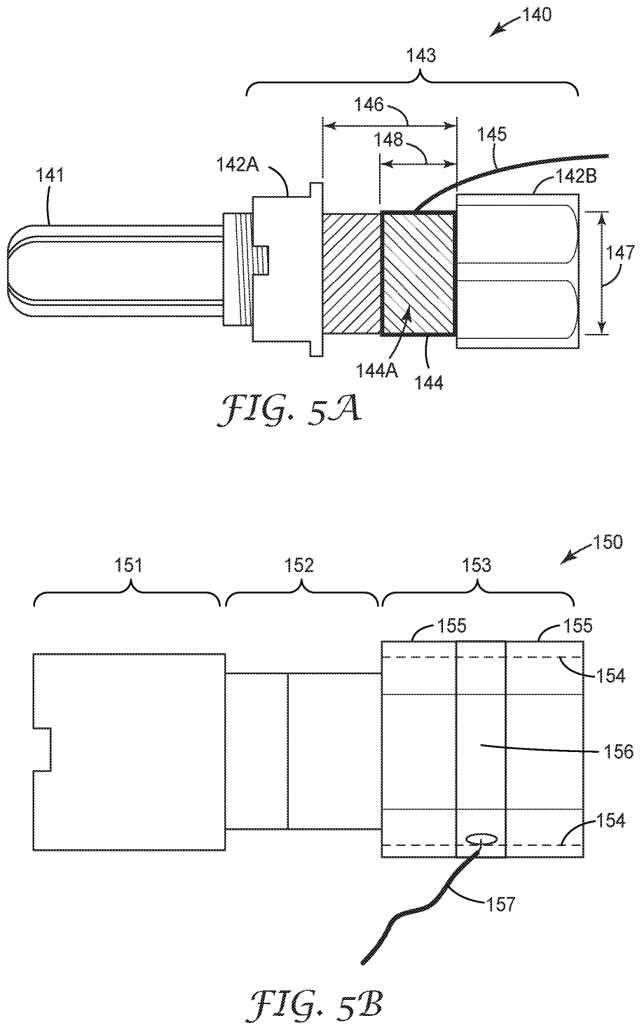

As shown in FIG. 4, electrical circuit 110 includes a capacitor 111 coupled to inputs of an opto-coupler 112. Outputs from the opto-coupler 112 are coupled through a voltage divider network 114, 115 to a reference (REF) output 116 and a control (CTRL) input 117 of an LED driver circuit 118. A first side of capacitor 111 is directly electrically coupled to electrical conductor 102 and/or terminal 104. Although the connection between the first side of capacitor 111 is shown contacting electrical conductor 102, in various examples the electrical conductor coupling the first side of capacitor 111 may contact terminal 104 instead. In various examples, the electrical conductor that couples the first side of capacitor 111 to electrical conductor 102 and/or terminal 104 is an insulated wire formed of a conductive metallic material, such as but not limited to copper. Although capacitor 111 is shown in FIG. 4 as a single capacitor, examples of capacitor 111 are not limited to comprising a single capacitor, and in some examples, may comprise a plurality of capacitors, in some examples coupled in series, as shown for example by capacitors 202 illustrated and described with respect to FIG. 8A-8C. In some examples, the first side of capacitor 111 is formed from some portion of the electrical conductor or the electrical terminal itself that is physically adjacent to and insulated from the second side of capacitor 111, for example in a manner of capacitor 144 illustrated and described with respect to FIGS. 5A and 5B.

Referring again to FIG. 4, a second side of capacitor 111 is electrically coupled to input pins 2 and 3 of opto-coupler 112. Input pins 1 and 4 are both electrically coupled to the common line 103 of cable 101. A first LED of opto-coupler 112 includes an anode coupled to pin 1 and a cathode coupled to pin 2 of the opto-coupler. The first LED of the opto-coupler is optically coupled to a first switching device coupling pins 7 and 8 of the opto-coupler 112, and is configured to control the first switching device with respect to switching the first switching device to an “ON” or an “OFF” state. A second LED of opto-coupler 112 includes an anode coupled to pin 3 and a cathode coupled to pin 4 of the opto-coupler. The second LED of the opto-coupler 112 is optically coupled to a second switching device coupling pins 5 and 6 of the opto-coupler 112, and is configured to control the second switching device with respect to switching the second switching device to an “ON” or an “OFF” state. In various examples, the first switching device and the second switching device operate as light sensing NPV semiconductor devices that may be switched to the “ON” state or to the “OFF” state based on receiving or not receiving, respectively, light transmitted from the first and second LEDs, respectively, of the opto-coupler 112. In some examples, a diode current of 150 μA through the first LED is needed to switch the first switching device that is optically coupled with the first diode to the “ON” state. Similarly, in some examples a diode current of 150 μA through the second LED of the opto-coupler 112 is needed to switch the second switching device that is optically coupled with the second diode to the “ON” state.

Pins 6 and 8 of the opto-coupler 112 are directly electrically coupled to the CTRL input 117 of driver circuit 118. Pins 6 and 8 are also coupled through resistance device 114 to the REF output 116 of the driver circuit. Pins 5 and 7 of opto-coupler 112 are electrical coupled to the common line 103 through resistive device 115. A source of low voltage DC power source, such as a +24 Volts DC power source, is provided to driver circuit 118 at the Vin+ input, and the Vin− input of the driver circuit 118 is electrically coupled to common line 103. In addition, driver circuit 118 includes a LED+ connection and an LED− connection arranged to provide an electrical output capable of causing illumination devices 105 to be driven to an “ON” state and provide illumination. In various examples, the illumination devices 105 comprise a plurality of series connected LEDs, and the electrical output provided by the LED+ connection and an LED− connection is a proper voltage and current to drive each of the plurality of LEDs to the “ON” illumination state, where the LEDs 105 emit one or more visible wavelengths of light. The LEDs 105 may be illumination devices provided in an illumination channel of an electrical coupler where electrical conductor 102 has been terminated at terminal 104, and wherein the illumination devices are configured to provide a visual indication of the presence of a minimum level voltage potential at the electrical conductor 102 and/or terminal 104 by being driven to an “ON” state of illumination when the minimum level voltage potential is present at the conductor 102 and/or terminal 104.

In operation, when the minimum level voltage potential is not present on electrical conductor 102, the capacitive voltage provided at input pins 2 and 3 of opto-coupler 112 is not sufficient to cause a current to flow through either of the diodes within opto-coupler, and so both the switching devices are in an “OFF” state. The REF output 116 is configured to provide a DC output voltage, such as +5 VDC, at all time when the LED driver circuit is powered by the +24 VDC. When both the switching devices of the opto-coupler 112 are in the “OFF” state, the voltage at the CTRL input 117 is pulled up through resistor 114 to the +5 VDC level, which the LED driver circuit 118 interprets as a condition wherein the minimum voltage potential is not present at the electrical conductor 102. When the +5V DC is provided to the CTRL input 117, in some examples, the LED driver circuit 118 does not provide an output power to the LED+ and LED− outputs, and therefore LEDs 105 are not powered and are not illuminated. LEDs 105 may include a plurality of LEDs positioned around a perimeter of an illumination channel, and when not illuminated, provide an indication that a minimum level voltage potential is not present at electrical conductor 102.

When a minimum level voltage potential is present at the electrical conductor 102, for example a medium voltage of 5 kV may be present at least during part of the voltage cycle when a voltage difference between the electrical conductor 102 and the common line 103 is sufficient, capacitor 111 acts as a capacitive ballast, creating a fixed current source between capacitor 111 and the inputs to the diodes of the opto-coupler 112. The diodes are arranged so that regardless of the polarity of the minimum voltage that is present at conductor 102, one of the diodes will receive a much smaller voltage level at its anode that is sufficient to create a current flow through that diode, and in turn the corresponding switching device for the LED experiencing the current flow will be switched to the “ON” state. When either of the switching devices is switched to the “ON” state, the switching device will provide an electrical path coupling the REF output 116 to the common line 103 through the voltage divider network formed by resistive devices 114 and 115. The voltage divider network is configured to provide a trigger voltage level, for example +2 VDC or less, at the CTRL input 117 when the resistor devices provide the above-described voltage divider function as a result of either of the switching devices of the opto-coupler 112 being in the “ON” state. The trigger voltage level input at the CTRL input 117 is interpreted by the LED driver circuit 118 as an indication of the presence of a minimum level voltage potential at electrical conductor 102. When the trigger level voltage is detected at the CTRL input 117, the LED driver circuit 118 in some examples may be configured to provide an electrical power output to the LED+ and LED− outputs that will cause LEDs 105 to be illumination, and thus to provide a visual indication of the presence of a minimum level voltage potential at electrical conductor 102.

Thus, in some configurations, when LEDs 105 are illuminated, the presence of a minimum level voltage potential is visually indicated by the illumination of LEDs 105. As described above, LEDs 105 may include a plurality of LED positioned at different locations around the perimeter of an electrical coupler and within an illumination channel formed as part of or provided around a portion of the electrical coupler, in an arrangement so that at least one LED of the plurality of LEDs 105 is visible from at least any angle perpendicular to a longitudinal axis of the electrical coupler where LEDs 105 are installed. In this manner, the status of the LEDs 105 may be visibly determined from at least any visible angle of the illumination channel that encircles of the electrical coupler and that is perpendicular to the longitudinal axis of the electrical coupler.

In some configurations, two different visual indications, such as different color illumination of the LEDs 105, may be provided by electrical circuit 110 and LEDs 105 depending on whether the minimum level voltage potential is or is not present at the electrical conductor 102. For example, as described above, when the minimum level voltage potential is not present at the electrical conductor 102, the CTRL input 117 of the LED driver circuit 118 is pulled up to the reference voltage level provided by REF output 116. LED driver circuit 118 may be configured to interpret this as an indication that the minimum level voltage potential is not present on electrical conductor 102, and may be configured to drive LEDs 105 for example with a first voltage level, or using a first input to the LEDs, that causes LEDs 105 to illuminate in a first manner, such as with a first color.

When the minimum level voltage potential is sensed at electrical conductor 102, as describe above the CTRL input 117 of the LED driver circuit 118 is pulled down to at or below a trigger voltage, which the LED driver circuit may be configured to interpret as an indication of the presence of the minimum level voltage potential at electrical conductor 102. In response to receiving a voltage level at the CTRL input 117 that is at or below the trigger voltage, LED driver circuit 118 may be configured to drive LEDs 105 for example with a second voltage level, or using a second input to the LEDS, that causes LEDs 105 to illuminate in a second manner, such as with a second color, that is different and visually distinguishable from the first manner or color. In this way, the LED driver circuit 118 and the LEDs 105 may be configured to provide a first visual induction when the minimum level voltage potential is not sensed at the electrical conductor 102, and to provide a second visual indication that is distinguishable from the first visual indication when the minimum level voltage potential is sensed as at the electrical conductor 102.

The minimum level voltage potential at electrical conductor 102 that is needed to trigger electrical circuit 110 to turn the LEDs 105 from and “OFF” state to the “ON” state, or to change the visual indication provided by LEDs 105 from a first indication to a different indication may be determined by the capacitance and the reactive capacitive value provided by capacitor 111 at the frequency range of voltages expected to be received on electrical conductor 102 in combination with the voltage drop across one of the LEDs coupled to the inputs of the opto-coupler 112. Capacitor 111 is configured to source or sink a current flow between capacitor 111 and a forward biased diode (LED) of the opto-coupler 112 so that when the minimum level voltage potential is present at electrical conductor 102, a voltage level at the input to the forward biased diode of the opto-coupler 112 provides a current flow through the diode, for example in a range of 40 to 60 milliamperes, that is sufficient allow the diode to illuminate to optically trigger the associated switching device to transition to the “ON” state. An example of a device that may be used to provide opto-coupler 112 is a Model TLP523-2 Optocoupler, Darlington Output, two-channel device manufactured by Toshiba Corporation, Headquarters 1-1 Shibaura 1-chome, Minato-ku, Tokyo Japan.

As shown in FIG. 4, additional electrical conductor 122 may be provided in cable 101 wherein cable 101 provides power electrical conductors configured to carry an electrical configure of power having more than one phase, such as a two-phase electrical power configuration. When present in cable 101, electrical conductor 122 may be directly couple to a terminal (not shown in FIG. 4) and a second electronic circuitry 120 provided within the same electrical coupler where electrical conductor 102, terminal 104, and electrical circuit 110 are located. In a similar manner as described above with respect to electrical circuits 110, electrical circuits 120 may include a capacitor configured to sense a voltage potential at conductor 122 or the terminal where electrical conductor 122 is couple to. Electrical circuit 120 further includes an opto-coupler, a resistive divider network, and a LED driver circuit configured to control the illumination of a set of LEDs 124 coupled to the output of the LED driver circuit of electrical circuit 120. Electrical circuit 120 may operate in a same manner and provide all of the features and functions described above with respect to electronic circuit 110, but with respect to the detection of an indication of a minimum level voltage potential at electrical conductor 122 and/or the terminal within the electrical coupler where electrical conductor 122 is terminated.

As also illustrated in FIG. 4, a third electrical conductor 132 may be provided in cable 101, wherein cable 101 provides power electrical conductors configured to carry an electrical configuration having three phases. When present in cable 101, electrical conductor 132 may be directly coupled to a terminal (not shown in FIG. 4) and to a third electrical circuit 130 provided within the same electrical coupler where electrical conductor 102, terminal 104, and electrical circuit 110 are located. In a similar manner as described above with respect to electrical circuit 110, electrical circuit 130 may include a capacitor configured to sense a voltage potential at conductor 132, or at the terminal where electrical conductor 132 is coupled to within the electrical coupler. Electrical circuit 130 further includes an opto-coupler, a resistive divider network, and a LED driver circuit configured to control the illumination of a set of LEDs 134 coupled to the output of the LED driver circuit of electrical circuit 130. Electrical circuit 130 may operate in a same manner, and provide all of the features and perform any of the same functions described above with respect to electrical circuit 110, but with respect to the detection of and providing an indication for a minimum level voltage potential at electrical conductor 132 and/or the terminal within the electrical coupler where electrical conductor 132 is terminated.

As shown in FIG. 4, the +24 VDC using to power the LED driver circuit 118 of electrical circuit 110, and to power the LED driver circuits of electrical circuit(s) 120 and/or 130 when these circuits are present may be provided as a non-power conductor included in cable 101. In some examples, the +24 VDC is provided by a power supply located externally to the electrical coupler illustrated in FIG. 4, and is provided to the electrical circuit(s) as illustrated in FIG. 4 by the non-power conductor provided in cable 101. The electrical conductor providing the +24 VDC electrical power is referred to as a non-power conductor because that electrical conductor is not one of the electrical conductors provided in cable 101 that is configured to be monitored for a minimum level voltage potential, wherein electrical conductor 102, and electrical conductor 122 and 132 when present, may be monitored for the presence of a voltage potential on the electrical conductor(s) by the circuits illustrated and described with respect to FIG. 4.

In some examples, individual ones of the LEDs from each of the plurality of LEDs 105, 124, and 134 may be grouped together to form sets or groups of LEDs so that each set or group contains at least one LED from each of the sets of LEDs 105, 124, 134. In addition, multiple sets or groups of these mixed sets or groups of LEDs may be positioned at a plurality of locations around a perimeter of an illumination channel so that from at least any angle of view perpendicular to the longitudinal axis of the electrical coupler, at least one set or group of these mixed sets of LEDs will be visible. In this manner, every such angle of view of the illumination channel will provide visual access to a least one LED from each of the plurality LEDs 105, 124, and 134, and thus provide an indication of the status of each electrical conductor 102, 122, 132 from each of these viewing angles.

In some examples, the output of the LED driver circuit may be electrically coupled between LEDs 105, 124, 134, as illustratively shown by dashed line 106. The electrical connection illustratively shown by dashed line 106 may be used to electrically couple multi-input/multi-color LED devices, provided as LEDs 105, 124, 134, in a manner so that each LED will provide a light emission when illuminated that is indicative of which ones of the three electrical conductors 102, 122, and/or 132 have the minimum level voltage potential present at the electrical conductor. For example, multi-input/multi-color LEDs may be provided for example as RGB LEDs, and electrically coupled (e.g., by dashed line 106), so that a red, green, blue color would be provided, respectively, when only one of the electrical conductors is at the minimum voltage potential. Magenta, yellow and cyan combinational colors can be provided, respectively by the LEDs when illuminated as a visual indication when a specific combination, respectively of only two of the three electrical conductors are at the minimum voltage potential level. A white color light may be provided by the LEDs when all three electrical conductors are at the minimum level voltage potential. The use of these different color combination provides a level of safety and additional convenience as a troubleshooting tool for using the visual indications provided by the illumination device at an electrical coupler to so that the color indicates specifically which phase of the electrical coupler are in fact present at the electrical coupler at any given time.

In various examples, one or more of the LED driver circuits included in electrical circuits 110, 120, and/or 130 may comprise a Luxdrive® BuckPuck Model 3201 LED Power Module, manufacture by LEDdynamics®, Inc., headquarters at 44 Hull Street, Randolf Vt. In various examples, one or more of LEDs 105, LEDs 124, and/or LEDs 134 may comprise a Model LRTB C9TP Multi-CERAMOS Enhanced Optical Power LED, manufactured by OSRAM Optical Semiconductors GmbH, Leibnizstrasse 4, D-93055 Regensburg, Germany.

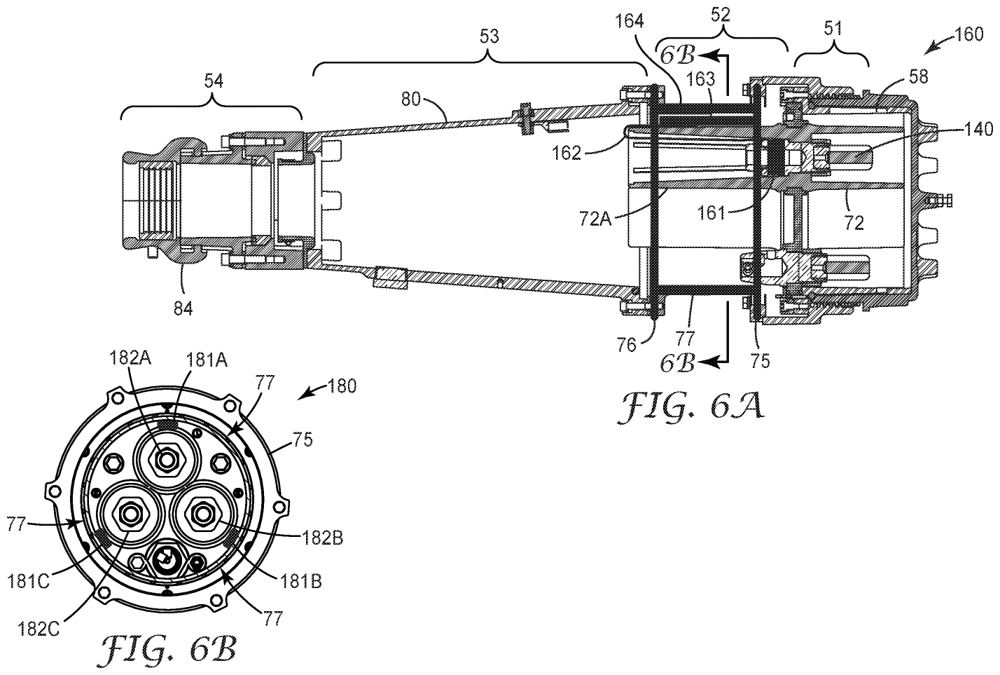

FIG. 5A illustrates an electrical terminal 140 including an example voltage sensing capacitor 144 in accordance with the devices and techniques described in this disclosure. As shown in FIG. 5A, terminal 140 includes a terminal 141 in the form of a male pin received in a front receptacle 142A of a collet 143. The end of collet 143 opposite the pin 141 includes a rear receptacle 142B arranged to accept an end of an electrical conductor received in an electrical coupler where the terminal 140 is configured to be installed. The electrical conductor may be one of the power electrical conductors arranged to carry the medium voltage electrical power that is to be coupled through the electrical coupler where terminal 140 is installed. The voltage sensing capacitor 144 is shown in FIG. 5A as surrounding a portion of the collet 143, and electrically coupled to additional electrical circuitry (not shown in FIG. 5A, but for example electrical circuit 163 illustrated and described below with respect to FIGS. 6A and 6B). A first plate of capacitor 144 may be formed by the portion of the collet 143 that is at least partially surrounded by the portion of capacitor 144 forming the second plate 144A of the capacitor. Second plate 144A of capacitor 144 may be electrically insulated from the collet 143, and form from a conductive layer of material, such as a copper foil, that is positioned adjacent to and surrounding a portion of the collet 143. Second plate 144A of capacitor 144 is electrically coupled to wire 145.

Capacitor 144 thus forms a capacitive ballast operating as a fixed current source between any voltage potential provided at collet 143 (and thus also at terminal 141), and the electrical circuit that may be coupled to wire 145. In this manner, capacitor 144 is configured to provide both a sensing device to sense a voltage potential at collet 143, and to provide a reduced voltage level at wire 145 that corresponds to the voltage potential present at collet 143 and terminal 141. The output voltage provided from capacitor 144 at wire 145 may be used to directly or indirectly drive additional electrical circuitry, including illumination devices, that may provide a visual and/or another form of indication with respect to the presence or absence of a voltage potential at collet 143 and terminal 141. For example, capacitor 144 may be an example of capacitor 111 illustrated and described with respect to FIG. 4, and wire 145 may be the input coupling capacitor 111 to the opto-input 112 and the LED driver circuit 118 that control the illumination of illumination devices, such as LEDs 105, based on the sensed and reduced voltages that may be provide at wire 145 by capacitor 144.

The dimensions of capacitor 144 are not limited to any particular dimensions, and may be dictated by the dimensions of the portion of the collet 143 where capacitor 144 is formed, and/or by the voltage levels that are intended to be sensed by the capacitor. In some examples, capacitor 144 has a circular shaped cross-sectional dimension having a diameter value of approximately 25 mm, and a width dimension 148 of approximately 18 mm. The portion of collet 143 were capacitor 144 is formed extends between the front receptacle 142A and the rear receptacle 142B, and may have a width dimensions 146 that is larger than the width dimension of the capacitor 144. In some examples, with dimension 146 is approximately 30 mm. The dimensions illustrated and described with respect to FIG. 5A are illustrative only, and dimensions of collet 143, terminal 141, and capacitor 144 may include devices having different dimensions than those depicted in FIG. 5A, for example for collets and capacitors that are designed to carry a different range or ranges of voltages and/or currents. Collets, terminals, and capacitors having dimensions that differ from those illustrated and described with respect to FIG. 5A are contemplated for use in providing capacitors for sensing and providing voltage reduction to electrical circuits used to control illumination of illumination devices as described throughout this disclosure, and any equivalents thereof.

FIG. 5B illustrates a collet 150 including an example voltage sensing capacitor 153 in accordance with the devices and techniques described in this disclosure. As shown in FIG. 5B, collet 150 includes a front receptacle 151, a neck portion 152, and a rear receptacle portion 154. In various examples, each portion 151, 152, and 154 of the collet 150 is formed of a same piece of an electrically conductive material, and thus are electrically coupled to one another. Front receptacle 151 may be configured to receive and electrically couple to a female or a male terminal configured to engage another terminal located in an electrical coupler that is coupled to the electrical coupler where collet 150 is installed. Neck portion 152 of collet 150 physically and electrically couples the front receptacle 151 to the rear receptacle 154. Rear receptacle 154 may be arranged to receive, secure, and electrically couple an end of an electrical conductor, such as a power electrical conductor. When an electrical conductor is received and secured within the rear receptacle 154 of collet 150, the electrical conductor is electrically coupled to the front receptacle 151, and thus to any pin or terminal positioned in the front receptacle 151.

Capacitor 153 includes and insulative layer 155 surrounding a portion of the exterior surface of the rear receptacle 154, and a conductive layer 156 forming a capacitive plate formed over the surface of the insulative layer 155 and opposite the surface of insulative layer 155 that faces the rear receptacle 154. Conductive layer 156 is electrically coupled to a conductive wire 157 configured to provide an electrical connection between the conducive layer 156 of capacitor 153 and an electrical circuit (not shown in FIG. 5A, but for example electrical circuit 163 illustrated and described below with respect to FIGS. 6A and 6B). As shown in FIG. 5B, the portion of rear receptacle 154 encircled by the conductive layer 156 forms a first plate of capacitor 153, and the conductive layer 156 forms the second plate of capacitor 153. The insulative layer 155 electrically insulates and physically separates the conductive layer 156 from the rear receptacle 154, and forms the dielectric layer of capacitor 153. The dielectric layer 155 may be formed using an adhesive tape, and conductive layer 156 may be formed of a copper tape that may be applied to and adhere to the dielectric layer.

The positioning of capacitor 153 at the collet 150 as described above allows a voltage potential at the collet 150 to be sensed by capacitor 153, wherein capacitor 153 provides a sensed and reduced voltage at wire 157 that corresponds to the voltage present at collet 150. The output voltage provided from capacitor 153 at wire 157 may be used to directly or indirectly drive additional electrical circuitry, including illumination devices, that may provide a visual and/or another form of indication with respect to the presence or absence of a voltage potential at collet 150. For example, capacitor 153 may be an example of capacitor 111 illustrated and described with respect to FIG. 4, and wire 157 may be the input that couples capacitor 111 to the inputs of opto-coupler 112 and the LED driver circuit 118 that controls the illumination of illumination devices, such as LEDs 105, based on the sensed and reduced voltages that may be provide at wire 157 by capacitor 153.

Dimensions related to capacitor 153 are not limited to any particular dimensions, and may be based on the size and dimensions of the rear receptacle 154, and by the voltages and currents intended to be carried by collet 150. In some examples, the construction of capacitor 153 as shown in FIG. 5B results in a capacitor having a capacitance of 40 pF.

FIG. 6A illustrates a cutaway view of an example electrical coupler 160 in accordance with various devices and techniques described in this disclosure. Electrical coupler 160 may be an example of any of electrical couplers 50 and/or electrical coupler 50A as illustrated and described with respect to FIGS. 2A, 2B, 3A, 3B, 3C, and 3D. As shown in FIG. 6A, electrical coupler 160 includes a terminal 140 installed in a terminal housing 72, 72A of the front portion 51 of the electrical coupler. In some examples, a sensing device 161, such as a capacitor similar to capacitor 144 as illustrated and described with respect to FIG. 5A or capacitor 153 as illustrated and described with respect to FIG. 5B, is arranged adjacent to the collet holding terminal 140, and configured to sense the presence of a voltage potential at the collet holding terminal 140. As shown in FIG. 6A, an electrical conductor 162 electrically couples the sensing device 161 to electrical circuit 163 located outside the extended portion of the terminal housing 72A, and within the illumination coupling 52 adjacent to the illumination channel 77.

Electrical circuit 163 may be further coupled to one or more illumination devices (not specifically shown in FIG. 6A, but for example illumination devices 78 illustrated and described with respect to FIGS. 3A-3C), that may be located along the outside surface 164 of the illumination coupling 52 and partially or wholly within the illumination channel 77, and positioned below the outmost extension of front flange 75 and rear flange 76 of the illumination coupling 52. Electrical circuit 163 may be configured to receive a voltage level sensed by sensing device 161 through electrical conductor 162, and to control illumination of the one or more illumination devices coupled to the electrical circuit 163 based on the level of the voltage potential received at the electrical circuit through electrical conductor 162. As shown in FIG. 6A, the combination of sensing device 161, electrical conductor 162, electrical circuit 163, and one or more illumination devices coupled to electrical circuit 163 may be arranged to sense a voltage potential on the collet holding terminal 140, and to provide a visible indication by illumination of the illumination devices located in the illumination channel 77 of the presence of a minimum level voltage potential at the collet and terminal 140.

FIG. 6A only illustrates the sensing device, electrical conductor, and electrical circuit for a single collet/terminal, for example representing one phase of a multiple phase electrical configuration that is to be received, secured, and physically terminated within the electrical coupler 160. However, additional sets of sensing devices, electrical conductors, and electrical circuits may be provided for additional collets, terminals, and/or electrical conductors configured to be received, secured, and/or terminated within electrical coupler 160, and are contemplated by the example of the electrical coupler 160 illustrated and described below with respect to FIG. 6B.

FIG. 6B illustrates a sectional view of an electrical coupler 180 in accordance with examples devices and techniques described in this disclosure. The sectional view as shown in FIG. 6B may be taken as a sectional view “6B” relative to electrical coupler 160 of FIG. 6A. As shown in FIG. 6B, illumination channel 77 encircles a portion of the outer perimeter of electrical coupler 180. First electrical circuit 181A may be associated with and may be electrically coupled to receive a voltage input corresponding to a voltage level present on the electrical terminal 182A. First electrical circuit 181A is positioned inside the illumination coupling 52 and between the terminal 182A and the illumination channel 77. First electrical circuit 181A may be configured to control the illumination of one or more illumination devices (not shown in FIG. 6 B) that are located within the illumination channel 77 to provide a visual indication of the presence of a minimum level voltage potential on electrical terminal 182A. The LEDs controlled by the first electrical circuit 181A may be arranged to provide a visible light emission the can be seen when viewing the illumination channel 77 whenever the illuminating devices are powered by the first electrical circuit 181A.

In a similar matter, a second electrical circuit 181B that is associated with and is electrically coupled to receive an electrical input corresponding to a voltage level that is present on the electrical terminal 182B is positioned inside the illumination coupling 52 and between the terminal 182B and the illumination channel 77. The second electrical circuit 181B is configured to control the illumination of one or more illumination devices (not shown in FIG. 6 B) that are located within the illumination channel 77 to provide a visual indication of the presence of a minimum level voltage potential on electrical terminal 182B. The LEDs controlled by the second electrical circuit 181B may be arranged to provide a visible light emission the can be seen when viewing the illumination channel whenever the illumination devices are powered by the second electrical circuit 181B.

As shown in FIG. 6B, a third electrical circuit 181C that is associated with and is electrically coupled to receive an electrical input corresponding to a voltage level that is present on the electrical terminal 182C is positioned inside the illumination coupling 52 and between the terminal 182C and the illumination channel 77. The third electrical circuit 181C is configured to control the illumination of one or more illumination devices (not shown in FIG. 6 B) that are located within the illumination channel 77 to provide a visual indication of the presence of a minimum level voltage potential on electrical terminal 182C. The LEDs controlled by the third electrical circuit 181C may be arranged to provide a visible light emission the can be seen when viewing the illumination channel whenever the illumination devices are powered by the third electrical circuit 181C.

In some examples, the LEDs controlled by electrical circuits 181A, 181B, and 181C may be arranged in sets or groups around the perimeter of the illumination channel 77, as described above for example with respect to LEDs 105, 124, and 134 as shown and described with respect to FIG. 4. In some examples, the LEDs controlled by electrical circuits 181A, 181B, and 181C of FIG. 6B may be arranged in sets or groups around the perimeter of the illumination channel and wired together to provide a multi-color visual indication of which of the terminals 182A, 182B, and 182C are at a minimum level voltage potential, as described above for example with respect to LEDs 105, 124, and 134 shown and described with respect to FIG. 4.

In various examples, the electrical coupler 180 is configured to receive a set of three electrical conductors intended to provide three-phase electrical power, wherein each of the electrical conductors is intended to carry one phase of the three-phase electrical power, and is coupled to one and only one of the electrical terminals 182A, 182B, and 182C included the electrical coupler. In these examples, the electrical circuits 181A, 181B, and 181C may be arranged to provide a visual indication of the presence and/or absence of a minimum level voltage potential on each of the three electrical conductors. In this way, electrical coupler 180 may provide any of the features and may be configured to perform any functions described throughout this disclosure associated with electrical couplers configured to provide an indication of the presence and/or absence of voltage potential(s) received within the electrical coupler via one or more of the electrical conductors received within the electrical coupler.

In an alternative example, electrical coupler 180 includes electrical terminals 182A, 182B, and 182C coupled to electrical circuits 181A, 181B, and 181C as described above. Each of the electrical circuits 181A, 181B, and 181C are configured to received voltage level indications corresponding to the voltage levels present on electrical terminals 182A, 182B, and 182C, respectively, and control the illumination of one or more illumination devices located partially or wholly within the illumination channel 77. In this particular configuration, electrical coupler 180 is not configured to receive a set of electrical conductors from outside the electrical coupler that are to be terminated within the electrical coupler. and for example may include a sealed end at the main body 53 (main body 53 as shown in FIG. 6A) opposite the illumination coupler, and/or may not include a cable clamp 54.

Instead of receiving a cable within the main body of the electrical coupler, these examples of the electrical coupler are designed to be used as a portable test tool. When used as a portable test tool, the electrical coupler 180 is not coupled to a cable or other electrical conductors received within the main body of the coupler, but instead is intended to be engaged at the front portion 51 of the electrical coupler to a mating electrical coupler so that the terminals 182A, 182B, and 182C are electrically coupled to corresponding terminals in the mating electrical coupler. Once the electrical coupler being used as the portable test tool is coupled to the mating electrical coupler, any voltage potentials present on the terminals of the mating electrical coupler will be electrically coupled to corresponding terminals 182A, 182B, and 182C of electrical coupler 180.

The sensing circuits, electrical circuits, and illumination devices of electrical coupler 180 may therefore sense and provide one or more indications, such as visual indication(s) provided by illumination devices in illumination channel 77, indicative of the presence and/or absence of the minimum level voltage potentials on terminals 182A, 182B, and 182C. These indications will correspond to the presence and/or absence of minimum level voltage potentials on the corresponding terminals and electrical conductors receive in the mating electrical coupler.

By virtue of the ability to engage the portable test version of electrical coupler 180 with other mating electrical couplers, the portable test version of the electrical coupler 180 provides a way to determine, via the indication(s) provide by the portable test version of the electrical coupler, the status of voltage potential(s) that may be present in the mating electrical coupler. Further, by not being coupled to a cable itself, or in some examples to any external power source other than the power provided from the mating electrical coupler, the electrical coupler 180 when configured in the test version may only comprising the front portion 51, illumination coupling 52, and in some examples a main body portion 53, thus allowing this version of the electrical coupler 180 to be easily carried, for example by a user or by maintenance personal.

The portability of the test version of electrical coupler allow the electrical coupler to be easily moved to various locations throughout an area, such as a mining environment or a factory, which utilizes electrical couplers in an electrical distribution system in order to apply the test versions of the electrical coupler 180 to other electrical couplers located throughout the area. Safety and convenience may be enhanced by use of the portable electrical coupler as described above for users connecting, disconnecting, and maintaining the electrical couplers in the electrical distribution system where the test version of the electrical coupler may be utilized for any of the reasons described above. This particular version of the electrical coupler as described above is not limited to the configuration described above with respect to FIGS. 6A and 6B, and may incorporate any of the devices and techniques for providing an indication of the presence and/or absence of voltage potentials within an electrical coupler as described throughout this disclosure, and any equivalents thereof.

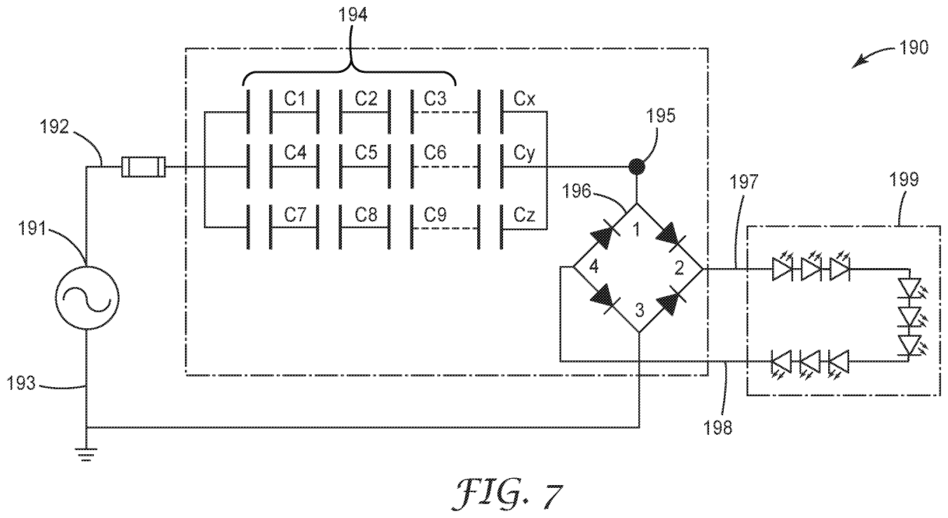

FIG. 7 illustrates a schematic diagram of an example electrical circuit 190 configured to sense and indicate a voltage potential in accordance with the devices and techniques described in this disclosure. As shown in FIG. 7, an electrical power source 191 includes a power output 192 and that is coupled to a reference voltage 193. In various examples, power output 192 represents one phase of single phase electrical power configuration provided by power source 191. In some examples, power output 192 represents one phase of a multi-phase electrical power configuration, such as a three-phase electrical power configuration provided by power source 191. In various examples, the electrical power provided by power output 192 is multi-phase AC electrical configuration provided with a phase-to-neutral voltage in a range of 2,000 to 8,000 Vrms. In some examples, the voltage may be 4200 Vrms multi-phase AC electrical power. However, the voltage and electrical power configuration provided to power output 192 by power source 191 is not limited to any particular voltage or range of voltages, and may be voltages other than 4200 Vrms RMS, and is not limited to any particular electrical configuration or to any particular number of phases of electrical power.

As shown in FIG. 7, power output 192 is electrically coupled to an input of a bank of series-parallel connected capacitors 194. In some examples, the coupling of the power output 192 to the bank of series-parallel connected capacitors 194 includes a protective device, such as the fuse illustrated in FIG. 7, to provide for example short-circuit and/or overload protection to the circuitry and devices coupled to power output 192. In some examples, capacitors 194 comprise NP0 or COG temperature rated type capacitors, each having a capacitance of 47 nF and a voltage rating of 2 kV. As shown in FIG. 7, capacitors 194 include capacitors C1, C2, and C3 through Cx coupled in series, capacitors C4, C5, and C6 through Cy coupled in series, and capacitors C7, C8, and C9 through Cz coupled in series. The series coupled capacitors C1, C2, and C3 through Cx are coupled in parallel to capacitors C4, C5, and C6 through Cy, and are also coupled in parallel to capacitors C7, C8, and C9 through Cz. Capacitors C4, C5, and C6 through Cy are coupled in parallel with capacitors C7, C8, and C9 through Cz. The dashed line coupling each of capacitors Cx, Cy, and Cz indicate that the number of capacitors that may be included in each of these strings of series coupled capacitors is not limited to three capacitors, or to a particular number of capacitors, and in some examples each string of series coupled capacitors may include three, four, or more capacitors. In various examples, the number of capacitors included in each of the series strings of capacitors depends on the voltage level that is to be provided to the capacitor bank at power output 192.

An output from the bank of series parallel connected capacitors 194 is coupled to node 195. Node 195 is also coupled to terminal 1 of a four-diode bridge circuit 196. Terminal 3 of the bridge circuit 196 is coupled to the reference voltage 193. Terminal 2 of the bridge circuit is coupled to an input 197 of a bank of series coupled LEDs 199. Terminal 4 of the bridge circuit is coupled to an output 198 of the series coupled LEDs 199.

In various examples, the portions of the electrical circuit 190 including capacitors 194, bridge circuit 196, and LEDs 199 are located within and/or provided as part of an electrical coupler, such as electrical coupler 50 shown in FIG. 2A or electrical coupler 50A shown in FIG. 2B. In various examples, capacitors 194 and bridge circuit 196 form electrical circuits used as the electrical circuit 66, 67 as illustrated and described in FIGS. 2A and 2B, and are physically located within the hollow space provided within the main body of these electrical couplers. In various examples, LEDs 199 are located partially or wholly within an illumination channel, such as illumination channel 77 illustrated and described with respect to FIG. 2A, or illumination channel 92 as illustrated and described in FIG. 2B. LEDs 199 may be used as the illumination devices in any of the examples of electrical couplers described throughout this disclosure as illumination devices, or any equivalents thereof.

In operation, when a medium voltage potential, such as the 4200 Vrms, is provided by power source 191 at power output 192, the voltage is coupled to the input of capacitors 194. The capacitors 194 will act as a capacitive ballast, and provide a reduced voltage, such as a voltage in the range of 10 to 50 volts, when the medium voltage potential is provided at power output 192. This reduced voltage is applied to terminal 1 of the bridge circuit 196. The bridge circuit is configured to provide a full wave rectified output between terminal 2 and terminal 4 of the bridge circuit when the low voltage output is present at node 195 and terminal 1 of the bridge circuit. The rectified output from the bridge circuit is applied between input 197 and output 198 of the LEDs 199, and will result in a current flow through the LEDs 199 the causes the LEDs 199 to be illuminated.

The LEDs 199 may be place around the perimeter of an illumination coupling, for example within an illumination channel of an electrical coupler, and provide a visual indication of the presence of the medium voltage potential at the electrical conductor and/or the terminal coupled to power source 191 through power output 192. For example, the illumination of LEDs 199 may provide a visual indication of the presence of the medium voltage potential at the power output 192.

By coupling the input to the capacitors 194 to a portion of the electrical conductor or a terminal within an electrical coupler coupled to the power output 192, the electrical circuit 190 may be used to sense the voltage potential at the electrical conductor or the terminal to which the input is coupled, and to provide a visual indication when the voltage potential is in fact present on the electrical conductor and/or the terminal within the electrical coupler. In various examples, electronic circuit 190 including capacitors 194 and bridge circuit 196 may be embedded in a resin or potting compound to insulate the electronic circuitry 190 from the high voltage and to further protect the electronic circuit 190 from mechanical impacts. The electronic circuitry 190 may be referred to as a “direct line driver” circuit because the electrical power used by the sensing circuits and any circuits used to control and power the illumination of the LEDs 199 for the detection of the high voltage potential at the electrical coupler is derived from the high voltage potential itself, and no additional outside power is required to operate the circuit(s) or to power the LEDs.

In some examples, a total capacitance Ctot for capacitor bank 194 may be calculated using the following equation:

Ctot=Np·C/Ns Equation (1)

wherein:
C is the capacitance of each capacitor in the capacitor bank and having a same capacitance value;
Np is the number of series-coupled strings of capacitors that are coupled in parallel to one another; and
Ns is the number of capacitors is series within a given series-coupled sting of capacitors.
   Considering that the voltage drop over the bridge circuit 196 is negligible and is therefore disregarded in the calculation, a current Iled that may be provided through LEDs 199 with an angular frequency ω of the input power provided to the capacitor bank 194, the total capacitance can also be calculated as follows:

Ctot=Np·C/Ns=Iled/(ω·Vline) Equation (2)

Wherein:
Iled is the current through the LEDs 199 in amperes
ω is the angular frequency in hertz; and
Vline is the voltage that is to be applied to the input of the capacitor bank 194.
   The number of series capacitances Ns is determined by the voltage rating Vcmax of each capacitor C such that:

Ns>(Vline·2)/Vcmax Equation (3)

wherein it is understood the Vline is a rms value.

In operation, the capacitors will dissipate some energy because of their equivalent series resistance ESR. Some manufacturers of the capacitors specify a dissipation factor, DF, by

DF=ωC·ESR Equation (4)

The power Pc dissipated in each capacitor may be given by:

Pc=(Iled/Np)²ESR<PcMax Equation (5)

And has an upper limit Pcmax of for example 250 mW for a small capacitor.
As an example, a ceramic C=3.6 [nF] capacitor with a Vcmax of 2 [kV] could be used to build a ballast for a line voltage Vline=4.2 kV at 50 Hz, and configured to provide a desired LED current Iled of 480 mA. A manufacturer of such a capacitor specifies a DF of 0.1% or 1e-3 leading to an ESR of 884Ω. Using Equation (3), Ns=4. Using Equation (5), Pc≈1.3 mW. In some examples, a design sequence for determining how to configure capacitor bank 194 comprises:
choosing an available C with certain VCmax and ESR and given Iled and Vline;
determine the required capacitive ballast Ctot from Equation (2);
determine Ns from Equation (3);
determine Np from Equation (2); and
checking, using Equation (4), if the dissipated power inequality is met. If not, choose a different C and repeat.

FIG. 8A illustrates an electrical schematic for an example sensing circuit 200 in accordance with the devices and techniques described in this disclosure. Sensing circuit 200 may be used in an electrical coupler, such as electrical coupler 50 as illustrated and described for example with respect to FIGS. 2A and 3A-3D, and such as electrical coupler 50A as illustrated and described for example with respect to FIG. 2B. Sensing circuit 200 may be used as the sensing portion of electrical circuitry used to control the illumination of one or more illumination devices associated with providing an indication of the presence of a minimum level voltage potential on an electrical conductor or terminal received, secured, and/or terminated within an electrical coupler. In some examples, sensing circuit 200 may form a part of the electrical circuits 66, 67 as illustrated and described with respect to FIGS. 2A and 2B.

As shown in FIG. 8A, input 201 may be an electrical conductor, such as a metallic wire, configured to be electrically coupled to a portion of a power electrical conductor, such as electrical conductor 102, 122, or 132 as illustrated and described with respect to FIG. 4, received within an electrical coupler, such as electrical coupler 50 or electrical coupler 50A. As shown in FIG. 8A, input 201 is coupled to a first side 202A of a set of series coupled capacitors 202. The series coupled capacitors 202 include an output 202B at the opposite end of the serial coupled capacitors relative to input 202A. Output 202B is coupled to node 203. Node 203 is coupled to an electrical lead 204, such as a conductive metallic wire. Node 203 is also coupled to a pair of serial coupled diodes 205, 206. Node 203 is coupled to a cathode of diode 205, and the anode of diode 205 is couple to the anode of diode 206. The cathode of diode 206 is coupled to an output 207. Output 207 may comprise an electrical conductor, such as a metallic wire. Output 207 may be coupled to a reference voltage, such as reference voltage 103, providing a reference voltage relative to the voltage potential to be couple to input 201. Diodes 205 and 206 are Zener diodes, coupled in an anti-series clamp arrangement as described above.

In operation, when a high or medium voltage potential is provided at an electrical conductor coupled to input 201, such as electrical conductors 102, 122, 132, the voltage potential is coupled to the input 202A of the capacitors 202 through input 201. Capacitors 202 provide a reactive capacitive ballast circuit with the diodes 205, 206 relative to the reference voltage 103 coupled to output 207. In various examples, the portion of the voltage provided at node 203 due to the voltage division occurring across capacitors 202 and the diodes 205, 206 is a much smaller voltage, for example in a range of 2 to 50 volts peak, compared to a value of hundreds or thousands of volts that may be provided at input 201. The electrical lead 204 coupled to node 203 provides the reduced voltage present between node 203 and output 207 across diodes 205, 206 and an output voltage. Because of the reduced voltage provided at node 203 even when much larger voltages are provided at input 201, the output voltage the occurs at node 203 and on electrical lead 204 may be used to directly or indirectly power electrical circuitry and illumination devices that provide a visual indication of the presence of the voltage potential at input 201 when the illumination devices are illuminated.

In an example configuration of a sensor circuit 200, the series coupled capacitors 202 are formed using eleven 2 kV, 3.6 nanoFarad (nF) capacitors in series, which provide an effective capacitance of approximately 300 picoFarad (pF), resulting in a reactive current in a range of approximately 1 milliamp when a 10 kV, 60 Hz line voltage is applied to the input 201. An example of a capacitor that may be used to provide the coupled capacitors is a device such as Digikey® part number 399-11280-1-ND capacitor manufactured by KEMET Corporation, headquarters at 2835 KEMET Way, Simpsonville, S.C. The diodes 205, 206 comprise two 3.4 volt Zener diodes, providing an output voltage in a range of 4 to 4.5 volts at node 203 and electrical lead 204.

The number, capacitance, and operating voltage range of capacitors 202 used to form the series capacitance is not limited to any particular number or type of capacitors, and may be configured using a positive number of capacitors each having a capacitance and an operating voltage range to provide a level of reactive voltage division at node 203 based on the particular voltage potential or range of voltage potentials that are to be provide at input 201. In addition, the diodes 205, 206 include Zener diodes configured to provide a voltage across the diodes in a range configured to provide a desired voltage level output at node 203 relative to the reference voltage intended to be coupled to reference voltage 103 and based on the intended voltage or range of voltages that are intended to be coupled to input 201 of the sensing circuit 200. In various examples, the low voltage provided across the combination of diodes 205, 206, and thus at node 203, may be in range of 5 to 25 volts.

In addition, diodes 205, 206 may comprise a single rectifying element or a varistor in some examples, or in alternate examples may comprise one or more series coupled diodes arranged so that the combined voltages provided across the diodes 205, 206 provides a desired low voltage level at node 203. The orientation of diodes 205, 206 as shown FIG. 8A assures that at least one of the diodes will be forward biased and one of the diodes will be reverse biased regardless of the polarity of the high or medium voltage provided an input 201 relative to the reference voltage coupled to output 207. In this manner, an approximately same voltage level output will be provided at node 203 and electrical lead 204 regardless of the polarity of voltage provided at input 201, assuming any polarity input voltages provided at input 201 have a same voltage level value, e.g., a same peak voltage level value at input 201 regardless of the polarity of the input voltage.

FIG. 8B illustrates a layout diagram of an example sensing circuit 200 in accordance with the example devices and techniques described in this disclosure. As shown in FIG. 8B, the capacitors 202 and diodes 205, 206 of the sensing circuit are mounted to a substrate 210, such as a circuit board. An electrical lead is coupled to input 201, and the capacitors 202 are electrically coupled in series to diodes 205, 206. An electrical conductor is electrically coupled to node 203, and another electrical lead is electrically coupled to output 207. In various examples, the capacitors 202 and diodes 205, and 206 are physically arranged in a linear arrangement along a longitudinal dimension 208 of the substrate 210. Substrate 210 also includes a width dimension 209 that is perpendicular and coplanar to the longitudinal dimension 208. In some examples, the longitudinal dimension 208 may have a value in the range of 25 to 50 centimeter (cm), and the width dimension 209 may have a value in the range of 2.5 to 5 cm.

A tubular structure 211, formed for example of a dielectric material such as Plexiglass® or polycarbonate, is also illustrated in FIG. 8B. Tubular structure 211 may comprise an outer wall surrounding a hollow opening running through the tubular structure 211 along the entirety of a longitudinal axis 212. A length dimension of tubular structure 211 may have a value that is greater than the longitudinal dimension 208 of sensing circuit 200, and the hollow opening of tubular structure 211 may have be circular-shaped in cross-section, and an inside diameter 213 having a value larger than the width diameter 209 of sensing circuit 200. The dimensions of tubular structure 211 may be such that the sensing circuit 200 can be received within the hollow opening within the tubular structure so that the outer wall of the tubular structure surrounds the substrate 210 at least along the longitudinal dimension 208. An opening 211A at a first end of tubular structure 211 may be used to allow the electrical conductor coupled to input 201 to extend through opening 211A and outside the hollow opening of the tubular structure. An opening 211B at a second end of the tubular structure 211 may be used to allow the electrical conductor 204 coupled to node 203 and the electrical conductor coupled to output 207 to extend through opening 211B and to an area outside the hollow opening of the tubular structure.

Once sensing circuit 200 is received within tubular structure 211 and the electrical conductors coupled to input 201, node 203, and output 207 have been extended to areas outside the tubular structure, some portion, most, or all of the hollow opening within the wall of the tubular structure may be filed will a potting or sealing compound, such as Sylgard 160 Silicon Elastomer manufactured by Dow Corning Corporation, Corporate Center 2200 W. Salzburg Rd., Auburn Mich., to secure and protect sensing circuits within the tubular structure.

The shape of the tubular structure is not limited to any particular shape, or to any particular shape in cross-section relative to the longitudinal axis, and may be any shape configured to enclose the sensing circuit 200 while allowing the electrical leads coupled to input 201, node 203, and output 207 to extend to area(s) outside the tubular structure. Other cross-sectional shapes, such as square, rectangular, triangular, and/or elliptical shapes are contemplated as shapes for one or more portions of the tubular structure.

FIG. 8C illustrates an electrical circuit assembly 220 in accordance with the example devices and techniques described in this disclosure. As shown in FIG. 8C, sensing circuit 200 formed on substrate 210 has been received within the hollow opening of tubular structure 211, and the electrical leads coupled to input 201 extend from the tubular structure 211 through opening 211A, and the electrical leads couple to node 203 and output 207 extend from the tubular structure 211 through opening 2111B. One or more examples of the electrical circuit assembly 220 may be installed and electrically coupled within an electrical coupler to provide the sensing circuitry used to sense a voltage potential at the portion of the one or more electrical conductors received within the electrical coupler, and to provide a low level voltage output corresponding to the sensed voltage potential that may be used to control, directly or indirectly, one or more indication devices, such as LEDs, to provide an indication of the presence and/or absence of the sensed voltage potential at input 201 of the assembly 220.

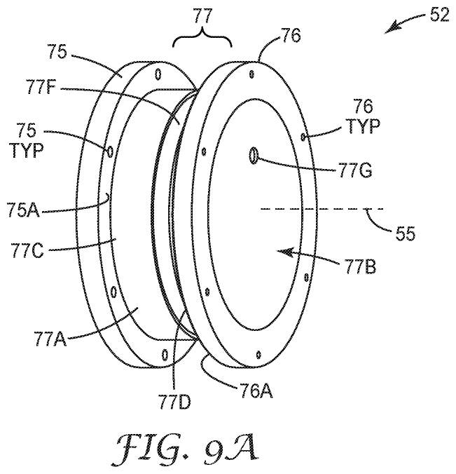

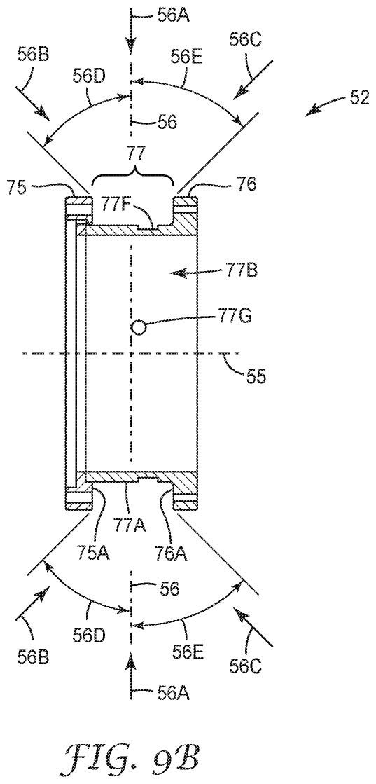

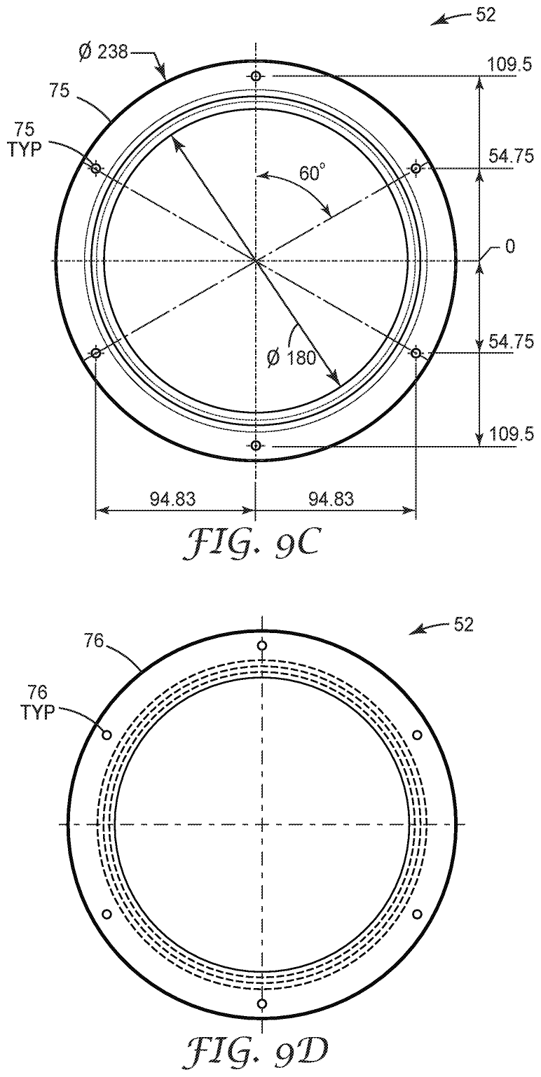

FIG. 9A illustrates a perspective view of an illumination coupling 52 in accordance with the example devices and techniques described in this disclosure. FIG. 9B illustrates a cutaway view of the illumination coupling 52 shown in FIG. 9A. As shown in FIGS. 9A and 9B, illumination coupling 52 includes a front flange 75 and a rear flange 76 separated by the illumination channel 77. Illumination channel 77 is formed from a cylindrical shaped wall structure having a cylindrical shaped outer surface 77A encircling an interior space 77B, the interior space 77B having a three-dimensional cylindrical shape. The front flange 75 comprises a cylindrical shaped flange encircling a portion of the interior space 77B, and is located at a front edge 77C of the illumination channel 77. Rear flange 76 comprises a cylindrical shaped flange encircling a portion of an interior space 77B, and is located at a rear edge 77D of the illumination channel 77. Each of front flange 75, illumination channel 77, and rear flange 76 encircle a hollow passageway forming the interior space 77B. The hollow passageway forming interior space 77B may have a circular shape in cross section that is perpendicular to longitudinal axis 55 running though the hollow passageway.

In various examples, front flange 75 extends beyond the outer surface 77A relative to longitudinal axis 55 to form a front side wall 75A of the illumination channel 77, the front side wall extending away from, and in some examples perpendicular to outer surface 77A. Rear flange 76 may extend beyond the outer surface 77A relative to longitudinal axis 55 to form a rear side wall 76B of the illumination channel 77, the rear side wall 76A extending away from, and in some examples perpendicular to the outer surface 77A.

The outer surface 77A may include a trough 77F having a width extending across some portion of the outer surface 77A between the front side wall 75A and the rear side wall 76A of the illumination channel. The trough 77F has depth the extends from the outer surface 77A toward the longitudinal axis 55, in some examples encircles a portion of the illumination channel 77 around a perimeter of the outer surface 77A. In various examples, the depth dimension of the trough 77F is less than a thickness of the illumination channel between the outer surface 77A and the interior space 77B such that the bottom surface of the trough 77F does not extent into the hollow opening of the interior space 77B.

In some examples, front flange 75 includes a plurality of holes 75typ that comprise opening through the front side wall 75A and the flange 75 to allow fasteners, such as machine screws, to be received within the opening to mechanically couple front flange 75 to a front portion of an electrical coupler, such as front portion 51 of electrical coupler 50 as illustrated and described with respect to FIGS. 2A and 2B. As shown in FIGS. 9A and 9B, rear flange 76 in some examples includes a plurality holes 76typ that comprise openings through the rear side wall 76A and the rear flange 76 to allow fasteners, such as machine screws, to be received in these openings to mechanically couple the rear flange 76 to a main body of an electrical coupler. The interior space 77B provides a passageway through illumination coupling 52 that may receive and allow one or more electrical conductors of a cable received in the electrical coupler to pass through the illumination coupling 52 between the main body and the front portion of the electrical coupler into which the illumination coupling may be incorporated. In addition, interior space 77B may also receive other portions of the electrical coupler. For example, a portion the terminal housing(s) provided with a front portion of an electrical coupler may extend into the interior space 77B when illumination coupling 52 is incorporated as part of the electrical coupler.

Further, the shape, the dimensions, and the placement of the openings 75typ of front flange 75 is not limited to the shape, the dimensions, and the placement of the openings shown in FIGS. 9A and 9B, and may be configured using other shapes, dimensions, and other patterns of openings that conform to a portion of the front portion of an electrical coupler to which the illumination coupling 52 is intended to be mechanically coupled with. Similarly, the shape, the dimensions, the placement of the opening 76typ of the rear flange 76 is not limited to the shape, the dimensions, and/or the placement of the openings 76type as show in FIG. 9A, and may be configured using other shapes, dimensions, and other placements of the opening to conform to a portion of a main body of an electrical coupler that the rear flange 76 of the illumination coupling is intended to be mechanically coupled with.

In various examples, illumination devices, such as LEDs, may be secured within the illumination channel 77, for example by placement within trough 77F, or secured to the side wall 75A and or side wall 76A of the front and rear flanges, respectively. The illumination devices may be wired to wiring provided as a wire bundle that extends to all the illumination devices located in illumination channel 77, and passes from the illumination channel to interior space 77B of the illumination coupling 52 through opening 77G extending from the outer surface 77A to the interior space 77B. The wiring bundle couples the wiring from the LEDs located in the illumination channel to one or more electrical circuits, such as electrical circuits 66,67 illustrated and described with respect to FIGS. 2A and 2B, or such as the LED driver devices illustrated and described with respect to FIG. 4, or for example to the sensing circuit 200 illustrated and described with respect to FIGS. 8A-8C. Any of these circuits may be used to control the illumination of the illumination devices that may be provided within the illumination channel 77 of the illumination coupling 52 as shown in FIGS. 9A and 9B.

FIG. 9B further illustrates possible viewing angles of the illumination channel 77, which when incorporated into an electrical coupler such as electrical coupler 50 as illustrated and described with respect to FIGS. 2A and 3A-3D, may provide visibility of light emissions being generated by the one or more illumination devices included partially or wholly within the illumination channel. As shown in FIG. 9B, longitudinal axis 55 is perpendicular to a plane, represented as dashed line 56, wherein plane 56 is oriented to be parallel with and located between the first flange 75 and the second flange 76. FIG. 9B views plane 56 looking into the edge of the plane. Viewing angles that are perpendicular to the longitudinal axis 55 may be illustratively shown as viewing angles that look directly at the edge of plane 56, for example as illustrated by arrows 56A in FIG. 9B. These perpendicular viewing angles may exist for any angle of view of plane 56 that is perpendicular to longitudinal axis 55 around the entirety of the perimeter of illumination channel 77 that encircles the longitudinal axis 55.

In addition, other viewing angles 56B, 56C of the illumination channel 77 may also provide viewing angles that provide visibility of the light emissions being generated by the one or more illumination devices included partially or wholly within the illumination channel. For example, angles of elevation 56D relative to plane 56 and extending away from plane 56 toward front flange 75, may provide additional angles of view of the light emissions from the illumination channel, as illustratively shown by arrow 56B. In addition, angles of elevation 56E relative to plane 56 and extending away from plane 56 toward rear flange 76, may provide additional angles of view of the light emissions from the illumination channel, as illustratively shown by arrow 56C. As shown in FIG. 9B, these additional angles of view may extend for any of these angles of view at some elevation relative to plane 56 around some portion or all of the entirety of the perimeter of illumination channel 77 that encircles the longitudinal axis 55.

Various factors, such as the positioning of the illumination devices within the illumination channel 77, the intensity of the light emissions, the reflectivity of the outer surface 77A, the front side wall 75A, and/or the rear side wall 76A and the light transmission properties of any cover or fill material provided within the illumination channel may contribute and/or control the range of the angles of elevation that may provide visibility of the light emissions provided by the illumination devices located partially or wholly within the illumination channel. In various examples, elevation angle 56D may comprise an angle of elevation of up to at least eighty-five degrees, and elevation angle 56E may comprise an angle of elevation of up to at least eighty-five degrees. As such, the overall construction of the illumination coupling 52, in conjunction with one or more of the factors described above, may allow for visibility of the light emission from the illumination channel over a span of viewing angles approaching one-hundred eighty degrees relative to the longitudinal axis 55.

FIG. 9C illustrates a side view of the example illumination coupling shown in FIG. 9A. The side view as shown in FIG. 9C illustrates the illumination coupling looking toward the front flange 75. The length dimensions shown in FIG. 9C are in units of millimeters. These length dimensions and angular value illustrated in FIG. 9C are intended to be non-limiting examples of dimensions and angular values that may be used to form an illumination coupling 52. Other length and/or angular dimensions are possible, and are contemplated for use in forming various examples of illumination couplings in accordance with the devices and techniques describe in this disclosure.

FIG. 9D illustrates another side view of the example illumination coupling shown in FIG. 9A. The side view as shown in FIG. 9D illustrates the illumination coupling looking toward the rear flange 76. The illumination coupling 52 as illustrated and described with respect to any of FIGS. 9A-9D may be provided as a part that is originally incorporated into an electrical coupler as provided by the manufacturer of the electrical coupler. In other examples, illumination coupling 52 as illustrated and described with respect to FIGS. 9A-9D may be provided as a part that can be used to retrofit an existing electrical coupler that was not originally provided with an illumination coupling or an illumination channel. The flange arrangement of the illumination coupling 52 may be configured in a variety of sizes and/or hole configures to allow versions of the illumination coupling to be used in the retrofitting of any number of different types, sizes, and styles of electrical couplers. In some examples, these retrofit versions of the illumination coupling may include illumination devices that are pre-positioned and pre-wired within the illumination channel of the illumination coupling. In some examples, these retrofit versions of the illumination coupling may include one or more electrical circuits that may or may not be pre-wired to the illumination devices.

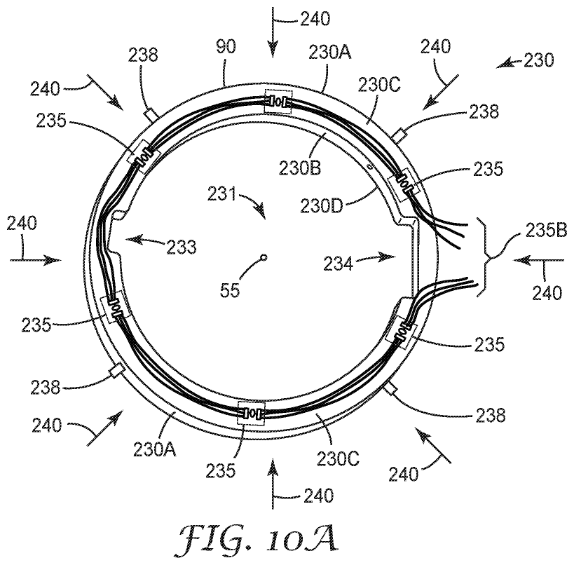

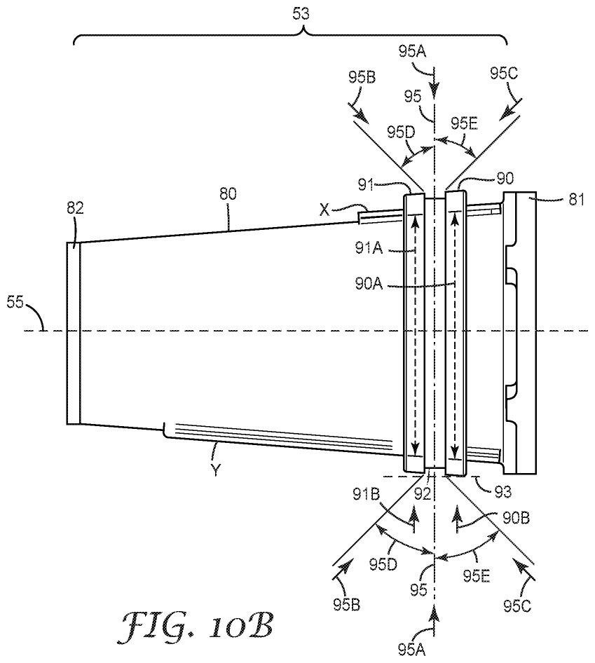

FIG. 10A illustrates an example illumination channel ring 230 in accordance with the devices and techniques described in this disclosure. Ring 230 may be an example of either or both of rings 90, 91 as illustrated and described with respect to FIG. 2B, and used to form one of a pair of side walls for an illumination channel, such as illumination channel 92, as shown and described with respect to FIG. 2B, around the exterior portion of the main body of an electrical coupler. As shown in FIG. 10A, ring 230 comprises a circular shaped material having an outer surface 230A separated from a parallel inner surface 230B by a pair of parallel sidewalls 230C and 230D extending between the outer surface 230A and the inner surface 230B. Surface 230D faces away from the view of ring 90 as illustrated in FIG. 10A, and is thus not visible in FIG. 10A. Outer surface 230A comprises a width dimension extending between the side walls 230C, 230D, and forming a perimeter encircling a longitudinal axis 55 of the ring. Inner surface 230B comprises a width dimension extending between the side walls 230C, 230D, and forming a circular shaped perimeter encircling the longitudinal axis 55 within the perimeter formed by outer surface 230A.

A plurality of fasteners 238, for example comprising set screws, may be positioned around the perimeter of ring 230 extending through the outer surface 230A, and configured to be extended through the ring 230 and the interior surface 230B in order to have a portion, such as a tip of each of the fasteners 238, brought into contact with the exterior surface 80 of the main body of the electrical coupler to secure ring 230 when positioned in the desired location along a main body of an electrical coupler. Fasteners 238 are configured so that the fasteners secure and maintain ring 230 in a fixed position on the main body of the electrical coupler relative to the longitudinal axis of the electrical coupler. In addition, cutouts 233, 234 extend from inner surface 230B into ring 230 toward outer surface 230A, and engage similarly shaped ridges on the exterior surface of the coupler, and may prevent rotation of ring 230 around the longitudinal axis of the main body of the electrical coupler once ring 230 is positioned on the main body of the electrical coupler.

In some examples, and inside diameter of the inner surface 230B at the inner side wall 230C may have a dimensional value that is less than the dimensional value of an inside diameter of the interior surface 230B at the outer side wall 230D. This difference in these dimensional values is configured to provide a “sloping surface” with respect to the inner surface 230B relative to the side walls 230C, 230D, the sloping surface matching the angle of taper formed by the exterior surface of the main body of the electrical coupler in the area of the main body where ring 230 is to be positioned. By providing the sloping surface, the interior surface 230B may be brought into contact substantially along the entire interior surface 230B with the exterior surface of the main body portion of the electrical coupler where the ring 230 is to be installed.

As shown in FIG. 10A, the side wall 230C may be used to secure a plurality of illumination devices 235 in place. The plurality of illumination devices 235 may be coupled to sensing circuitry (not shown in FIG. 10A), or to sensing circuitry and additional electronic circuitry (not shown in FIG. 10A), configured to sensed voltage potential(s) and to control the illumination of the illumination devices 235 to provide a visual indicated corresponding to the sensed voltage potential(s). As shown in FIG. 10A, electrical connections, such as wires, may be run along the interior side wall 230C to electrically couple the illumination devices 235 to sensing circuitry and/or LED driver circuitry and other circuitry configured to control the illumination of illumination devices 235 though wiring bundle 235B. In various examples wiring bundle 235B extends from the illumination channel through an opening in the main body of an electrical coupler where ring 230 is installed, and provides for the electrical coupling of the illumination device 235 to the sensing circuitry and/or the electrical circuitry used to control the illumination of the illumination devices within the main body and/or the front portion of the electrical coupler.

Further, in creating an illumination channel using rings installed over the outer portion of the main body of the electrical coupler, a second ring may be installed adjacent to the first ring 230 at a distance away from the ring 230 relative to the longitudinal axis of the electrical coupler, the distance between the ring 230 and the second ring forming a width of the illumination channel. The second ring may also have the sloped inner surface as describe above for inner surface 230B of ring 230. However, because the second ring will be installed at a different position along the main body having different exterior surface dimensions relative to the position where ring 230 is to be installed, the interior dimensions of the second ring may be different, for example being smaller in value compared to the value of the interior dimensions of the ring 230. The difference in dimensions allow for a spacing between the rings that may be used to form the illumination channel, as further described below with respect to FIG. 10B. Ring 230 may be installed on the electrical coupler so that side wall 230C faces the second ring installed on the coupler in order to position illumination devices 235 in the illumination channel created between the two rings.

FIG. 10B illustrates an example of a pair of rings 90, 91 that are installed on a main body 53 of an electrical coupler to form an illumination channel 92 in accordance with the devices and techniques described in this disclosure. As shown in FIG. 10B, ring 90 is positioned to encircle a portion of the exterior surface 80 of main body 53 of an electrical coupler. The rear flange 82 of the main body has an exterior surface having a smaller cross-sectional diameter relative to the longitudinal axis 55 compared to the cross-sectional diameter of the exterior surface 80 at the front flange 81 of the main body. In the examples illustrated in FIG. 10B, exterior surface 80 increases in cross-sectional dimension relative to longitudinal axis 55 from the rear flange 82 to the front flange 81, forming a sloped surface between the flanges relative to the longitudinal axis.

The interior surface 90A of ring 90 is dimensioned to include a sloped surface relative to the longitudinal axis 55 that matches the sloped surface and the dimensions of the exterior surface 80 at position 90B along the main body 53. In addition, ring 90 may also include cutouts having dimensions, shapes, and cutout positions along the interior surface of ring 90 to accommodate the ridges X and Y extending from the exterior surface 80 at position 90B of main body 53. When installed on main body 53, the interior surface 90A of ring 90 is dimensioned and shaped so the that substantially all of interiors surface 90A of ring 90 may be brought into physical contact with the portion of exterior surface 80 of the main body 53 at position 90B.

In a similar manner, the interior surface 91A of ring 91 may be dimensioned to include a sloped surface relative to the longitudinal axis 55 that matches the sloped surface and the dimensions of the exterior surface 80 at position 91B along the main body 53. In addition, ring 91 may also include cutouts having dimensions, shapes, and positioned along the interior surface 91A of ring 91 to accommodate the ridges X and Y extending from the exterior surface 80 at position 91B of main body 53. When installed on main body 53, the interior surface of ring 91 is dimensioned and shaped so the that substantially all of interior surface of ring 91 may be brought into physical contact with the portion of exterior surface 80 of the main body 53 at position 91B.

By providing specific dimensions to the interior surfaces of both ring 90 and ring 91, the position of contact between the interior surfaces 90A, 91A of the rings and exterior surface 80 of the main body 53 can be pre-defined in such as way that the final positioning of the rings 90 and 91 relative to the main body 53, and relative to each other, may also be pre-defined. For example, by providing pre-defined shapes and dimensions for the interiors surface of ring 90, the position 90B along longitudinal axis 55 when the main body 53 is receive within ring 90 and ring 90 is advanced to a maximum possible position toward the front flange 81 allowable by the dimensions of interior surface 90A and the dimensions of exterior surface 80, may be pre-defined to be position 90B of the main body 53. Similarly, by providing pre-defined shapes and dimensions for the interior surface 91A of ring 91, position 91B along longitudinal axis 55 when the main body 53 is receive within ring 91 and ring 91 is advanced to a maximum possible position toward the front portion 81 allowable by the dimensions of interior surface 91A and the dimensions of exterior surface 80 may be pre-defined to be position 91B of the main body 53.

By designing rings 90 and 91 as described above to assume positions 90B and 91B, respectively, when fully advanced onto the main body 53, the position of the illumination channel 92 relative to main body 53 is also pre-defined. In addition, the spacing between rings 90 and 91 when fully advanced onto main body 53 also defines a width for the illumination channel 92. The height of the sidewalls of rings 90 and 91 may also define a depth for the illumination channel 92. However, as show in FIG. 10B, the outermost surface of the illumination channel 92 may be below the outmost surfaces of rings 90 and 91 relative to the longitudinal axis. The arrangement allows the portions of rings 90 and 91 that extend beyond the outermost surface of the illumination channel to provide physical protection to the illumination channel and the illumination devices located within the illumination channel. The extended outer surfaces of rings 90 and 91 may be unequal, as illustrated by dashes line 93, to conform to the taper of exterior surface 80 of the main body 53. By matching the change in level of the exterior surface 80 with the uneven levels of the outer surfaces of rings 90, 91, the levels of stress imparted on the main body 53 may be reduced for example when the electrical coupler is laying on a relatively flat surface such as the ground. These unequal outer surfaces may reduce the level of stress placed on the main body 53 when the electrical conductor is placed on a level surface, such as on the ground or a paved surface such as a roadway or a floor of a building. In the example illustrated in FIG. 10B, electrical wiring coupled to the illumination devices may include a wire bundle that is routed through an opening in the exterior surface 80 of the main body 53 somewhere within the portion of the exterior surface that is encircled by the illumination channel.

Because rings 90 and 91 are configured to be installed over a main body of an electrical coupler, the rings may be provided in pairs that are designed, shaped, and dimensioned to be installed on the main body of an existing electrical coupler in order to retrofit the existing electrical coupler to include an illumination channel and illumination devices within the illumination channel that may provide a visual indication of the presence of a voltage potential on the electrical conductor(s) that may be received, secured, and/or terminated within the retrofitted electrical coupler. Rings 90, 91, illumination devices, and one or more electrical circuits configured to control the illumination of the illumination devices based on a detected voltage potential at one or more of the electrical conductor or electrical terminals received, secured, and/or terminate within an electrical coupler may be installed on the electrical coupler to retrofit the electrical coupler to provide the features and to perform the functions of an electrical coupler 50A illustrated and described with respect to FIG. 2B.

The illumination channel 92 may be filled with a transparent or translucent filler, such as a potting compound such as silicon, or with a translucent insert made of either a rigid or semi-flexibly transparent plastic material, such as a Plexiglass® material. An example of an illumination insert for an illumination channel is further illustrated and described below with respect to FIG. 11. In some examples, a pair of rings 90, 91, a plurality of pre-wired illumination devices, and one or more electrical control circuits configured to sense voltage potentials and to control the illumination of the illumination devices based on these sensed voltage potentials, may be provided as a kit for use in retrofitting an existing electrical coupler. The kit may be configured to allow an existing electrical coupler to be upgraded, using the kit, to provide one or more of the features and to allow the electrical coupler to perform one or more of the functions described throughout this disclosure with respect to the voltage sensing devices and sensing circuitry, the illumination couplings, the illumination devices, and the illumination channels.

The kits may be provided in a wide range of configurations with respect to ring shapes and sizes, and with respect to the types of electrical circuits and/or illumination devices that may be provided with the kit in order to accommodate a wide range of different sizes and shapes of electrical couplers, operating over a wide range of different electrical parameters with respect to the voltages, the current carry capacities, and/or the number of conductors that the electrical coupler is designed to connect and disconnect.

FIG. 10B further illustrates possible viewing angles of the illumination channel 92, which when incorporated into an electrical coupler such as electrical coupler 50A as illustrated and described with respect to FIG. 2B, may provide visibility of light emissions being generated by the one or more illumination devices included partially or wholly within the illumination channel. As shown in FIG. 10B, longitudinal axis 55 is perpendicular to a plane, represented as dashed line 95, wherein plane 95 is oriented to be parallel with and located between ring 90 and ring 91. FIG. 10B views plane 95 looking into the edge of the plane. Viewing angles that are perpendicular to the longitudinal axis 55 may be illustratively shown as viewing angles that look directly at the edge of plane 95, for example as illustrated by arrows 95A in FIG. 10B. These perpendicular viewing angles may exist for any angle of view of plane 95 that is perpendicular to longitudinal axis 55 around the entirety of the perimeter of illumination channel 92 that encircles the longitudinal axis 55.

In addition, other viewing angles 95B, 95C of the illumination channel 92 may also provide viewing angles that provide visibility of the light emissions being generated by the one or more illumination devices included partially or wholly within the illumination channel. For example, angles of elevation 95D relative to plane 95 and extending away from plane 56 toward ring 91, may provide additional angles of view of the light emissions from the illumination channel, as illustratively shown by arrow 95B. In addition, angles of elevation 95E relative to plane 95 and extending away from plane 95 toward ring 90, may provide additional angles of view of the light emissions from the illumination channel, as illustratively shown by arrow 95C. As shown in FIG. 10B, these additional angles of view may extend for any of these angles of view at some elevation relative to plane 95 around some portion or all of the entirety of the perimeter of illumination channel 92 that encircles the longitudinal axis 55.

Various factors, such as the positioning of the illumination devices within the illumination channel 92, the intensity of the light emissions, the reflectivity of the surface of the main body 53 located between the rings 90, 91, the reflectivity of the side wall portions of rings 90, 91 included within the illumination channel, and the light transmission properties of any cover or fill material provided within the illumination channel may contribute and/or control the range of the angles of elevation that may provide visibility of the light emissions provided by the illumination devices located partially or wholly within the illumination channel. In various examples, elevation angle 95D may comprise an angle of elevation of up to at least eighty-five degrees, and elevation angle 95C may comprise an angle of elevation of up to at least eighty-five degrees. As such, the overall construction of the illumination channel 92, in conjunction with one or more of the factors described above, may allow for visibility of the light emission from the illumination channel over a span of viewing angles approaching one-hundred eighty degrees relative to the longitudinal axis 55. In various examples, elevation angle 95D may have a maximum viewing angle that is different from, for example larger in value, than maximum viewing angle of elevation angel 95E due the differences in the distances of the outside perimeters of rings 90, 91 relative to longitudinal axis 55.

FIG. 11 illustrates an example illumination insert 250 in accordance with the devices and techniques described in this disclosure. In various examples, illumination insert 250 is illumination insert 79 shown and described with respect to FIG. 3D. Illumination insert 250 as illustrated in FIG. 11 may be installed in an any of the illumination channels described throughout this disclosure, or any equivalents thereof, in order to perform one or more function related to the illumination devices, including providing physical protection to the illumination devices located within the illumination channel where the illumination insert 250 is installed.

As shown in FIG. 11, illumination insert 250 includes and exterior surface 250A having a width and forming a perimeter encircling a longitudinal axis 255 extending through the illumination insert 250. Illumination insert 250 also includes an interior surface 250B coupled to the outer surface 250A by a first side wall 250C and a second side wall 250D, the interior surface 250B having a width and forming a perimeter encircling the longitudinal axis 255 at a distance or distances that are less than the distance or distance of the perimeter of outer surface 250A. Side walls 250C and 250D may form walls that lie in separate parallel planes that are perpendicular to longitudinal axis 255. The interior surface 250B may form a perimeter encircling an opening 251 running through the illumination insert 250 for the width of the outer surface 250A and the width of the inner surface 205B.

In some examples, illumination insert 250 further includes one or more junctions 245A, 245B, positioned around the perimeter of illumination insert 250, and configured to allow coupling of a first portion 254C of the ring 250 with a second portion of ring 250. In some examples junctions 245A, 245B are releasable junctions that are configured to allow the first portion 245C to be physically attached together with the second portion 245D so that illumination insert 250 may be installed within an illumination channel and over illumination device(s) already in position within the illumination channel. Illumination insert 250 may comprise a clear or translucent material that allows light emissions generated by the illumination devices to radiate through the illumination insert 250 and be visible outside the illumination channel. In some examples, illumination insert 250 may operate as a light pipe and transmit light emissions for one or more illumination devices to other location around the perimeter of the outer surface 250A of the illumination insert to help provide emission of the light to all portions of the illumination channel that surrounds a main body of an electrical coupler. In some examples, illumination insert 250 performs a light mixing function by mixing wavelength of different colors of light being emitted by different illumination devices located within an illumination channel in order to provide a light emission from the illumination channel where the illumination insert is install having a wavelength or wavelengths comprising the mixed wavelengths.

In some examples, the insert provides both light mixing for both color rendering purposes and light uniformity by incorporating extraction features or diffusion properties in the surface and/or bulk matrix of the insert. These features of the insert may be useful if illumination devices providing color light emissions are not co-located in a same location, for example on a same die, within the illumination channel. In some examples, an illumination channel included in an illumination coupling or formed using rings on a main body of an electrical coupler may include a plurality of illumination devices, such as LEDs, provided on a colored tape that provides a color to the light emissions provided by the illumination devices. The colored tape may be filled over within the illumination channel with a transparent resin that further protects the illumination devices. In some examples, the resin used to fill the illumination channel over the illumination devices may be transparent and/or translucent, and impart a color to the light emissions being emitted by the illumination devices to provide color or a mix of colors to the light emissions exiting the illumination channel.

FIG. 12 illustrates a flowchart of an example method 300 in accordance with the devices and techniques described in this disclosure. Although method 300 is described below as being performed by electrical coupler 50 as illustrated and described for example with respect to FIG. 2A and FIGS. 3A-3D, the example method 300 is not limited to the example implementations illustrated with respect to electrical coupler 50. In various examples, the techniques and devices of examples of method 300 may be implemented in whole or in part, by other variations of electrical couplers described throughout this disclosure, and any equivalents thereof, such as electrical coupler 50A as described and illustrated with respect to FIG. 2B and FIGS. 10A and 10B.

In various examples of methods 300, electrical coupler 50 includes one or more electrical circuits, such as electrical circuits 66, 67, configured to sense voltage potential(s) on one or more electrical conductors that are received within the electrical coupler (block 302). In various examples, electrical circuits include a capacitor arranged to sense a voltage potential present on one of the one or more electrical conductors received within the electrical coupler 50. The capacitor arranged to sense a voltage potential can be a capacitor formed on a collet within the electrical coupler, such as capacitor 144 illustrated and described with respect to FIG. 5A, or a capacitor 153 as illustrated and describe with respect to FIG. 5B. In some examples, the capacitor arranged to sense a voltage can be a plurality of capacitors, arranged for example in a series-parallel configuration as shown by capacitors 194 in FIG. 7, or a series coupled plurality of capacitors, as shown for example by capacitors 202 in FIG. 8A.

Method 300 further includes controlling the illumination of illumination device(s) arranged around the outside perimeter of the electrical coupler 50 based on the sensed voltage potential(s) (block 304). In various examples, controlling the illumination of the illumination device(s) includes providing a reduced sensed voltage level to control an LED driver circuit, such as the opto-coupler 112, voltage divider network formed by resistors 114, 115, and the LED driver circuit 118 illustrated and described with respect to FIG. 4. In various examples, the control circuitry may include the capacitors 194 coupled to a bridge circuit 196 as illustrated and described with respect to FIG. 7. In various examples, the control circuitry may include capacitors 202 and series coupled diodes 205, 206 as illustrated and described with respect to FIG. 8A. The illumination devices being controlled by the electrical circuits may be LEDs that are arranged in an illumination channel 77 of an illuminating coupling 52 provided as part of electrical coupling 50. Examples of the illumination coupling having an illumination channel are illustrated and described with respect to FIGS. 9A-9D. The electrical wiring of the illumination devices to the electrical circuits that are configured to control the illumination of the illumination devices is illustrated and described for example with respect to FIG. 10A.

Control of the illumination of the illumination devices according to method 300 may include any of the control techniques for illumination of the illumination device to provide an indication of the presence and/or absence of a voltage potential that is sensed on a portion of and electrical conductor that is received, secured, and/or terminated within electrical coupler 50, or an electrical terminal provided within the electrical coupler 50. Illumination of the illumination devices may include control of the illumination devices to provide a visual indication of the presence and/or absence of a voltage potential or voltage potentials within the electrical coupler 50 around the outside perimeter of the electrical coupler 50 that is visible from any angle encircling the electrical couple that is perpendicular to a longitudinal axis of the electrical coupler. Control of the illumination of the illumination devices may include control of the illumination devices to provide a visible color light output, the color light output indicative of the presence and/or absence of a voltage potential on each of a plurality of power electrical conductors provided within the electrical coupler 50.

Various examples have been described. These and other examples are within the scope of the following claims.

1. A device comprising:
an illumination coupling comprising a front flange configured to be coupled to a front portion of an electrical coupler, a rear flange configured to be coupled to a main body of the electrical coupler, and an illumination channel extending between the front flange and the rear flange;
a plurality of illumination devices positioned at least partially within the illumination channel and configured to illuminate to provide a visible light emission viewable outside the illumination channel; and
one or more electrical circuits electrically coupled to the plurality of illumination devices, the one or more electrical circuits configured to sense the presence of a minimum level voltage potential on at least one of the one or more electrical conductors or terminals received within the electrical coupler, and to control the illumination of the plurality of illumination devices based on the detected presence of the minimum level voltage potential.

2. The device of claim 1, wherein the front flange, the rear flange, and the illumination channel are formed from a single piece of cast aluminum.

3. The device of claim 1, wherein the illumination channel is configured to encircle a hallow passageway forming an interior space within the illumination coupling.

4. The device of claim 1, wherein the plurality of illumination devices comprise light-emitting-diodes.

5. The device of claim 1, wherein the plurality of illumination devices are positioned at least partially within the illumination channel to provide the visible light emission viewable outside the illumination channel from at least any angle of view of the illumination channel that is perpendicular to a longitudinal axis of the illumination coupling.

6. The device of claim 1, wherein at least one of the one or more electrical circuits comprises:
a sensing capacitor having a capacitor input and a capacitor output, the capacitor input electrically coupled to one of the one or more electrical conductors or terminals received within the electrical coupler, and
a plurality of diodes coupled to the capacitor output and to a reference voltage,
wherein the sensing capacitor forms a capacitive ballast circuit between the capacitor input and the plurality of diodes, the capacitive ballast circuit configured to provide a reduced voltage output when the minimum level voltage potential is present at the capacitor input, the reduced voltage output configure to control the illumination of the plurality of illumination devices based on the detected presence of the minimum level voltage potential at the one of the one or more electrical conductors or terminals.

7-9. (canceled)

10. The device of claim 6, wherein the reduced voltage output comprises a voltage level that is directly coupled to one or more of the plurality of illumination devices to illuminate the one or more illumination devices in response to detection of the minimum level voltage potential at the capacitor input.

11. The device of claim 6, wherein the at least one of the one or more electrical circuits further comprises:
an opto-coupler configured to receive the reduced voltage output, and to provide a control voltage output based on a voltage level provided by the reduced voltage output, and
a driver circuit including a control input coupled to the pair of opto-coupler outputs and a driver circuit output coupled to one or more of the plurality of illumination devices, the driver circuit configured to receive the control voltage output at the control input of the opto-coupler and to provide electrical power to the one or more illumination devices coupled to the driver circuit outputs to illuminate the one or more illumination devices in response to detection of that the voltage level at the reduced voltage output corresponds to the minimum level voltage potential is detected at the capacitor input.

12. The device of claim 11, wherein the driver circuit is configured to control the illumination of the one or more illumination devices to provide a first color of visible light when the minimum level voltage potential is detected, and to control the illumination of the one or more illumination devices to provide a second color of visible light that is different from the first color of visible light when the minimum level voltage potential is not detected.

13. The device of claim 1, further comprising:
an illumination insert located within the illumination channel and configured to cover the one or more illumination devices, the illumination insert further configured to perform a light mixing function by mixing wavelengths of different colors of light being emitted one or more illumination devices in order to provide a light emission from the illumination channel having a wavelength or wavelengths comprising the mixed wavelengths of different colors of light.

14. The device of claim 1,
wherein the one or more electrical conductors or terminals include three power electrical conductors received within the electrical coupler, each of the three power electrical conductors configured to provide electrical power associated with one phase of a three-phase alternating current electrical configuration, and
wherein the one or more electrical circuits comprise three electrical circuits, each of the three electrical circuits electrically coupled to one and only one of the three power electrical conductors and configured to control the illumination of one or more of the plurality of illumination devices based on the sensed presence of a minimum level voltage potential at the one and only one electrical conductor.

15. A device comprising:
an electrical coupler comprising a main body and a front portion mechanically coupled to the main body, the electrical coupler configured to receive within the electrical couple one or more electrical conductors configured to carry electrical power;
a first ring having an interior surface, side walls, and an outer surface, the interior surface of the first ring having a shape and having dimensions configure to allow the first ring to be encircle the main body at a first position along the main body;
a second ring having an interior surface, side walls, and an outer surface, the interior surface of the second ring having a shape and having dimensions configured to allow the second ring to encircle the main body at a second position along the main body, the second position spaced apart from the first position relative to a longitudinal axis of the electrical coupler to provide an illumination channel encircling the portion of the main body between the first ring and the second ring;
a plurality of illumination devices positioned at least partially within the illumination channel and configured to provide visible light emissions when illuminated; and
one or more electrical circuits electrically coupled to the plurality of illumination devices, each of the one or more electrical circuits configured to detect the presence of a minimum level voltage potential on at least one of one or more electrical conductors received within the electrical coupler, and to control the illumination of the plurality of illumination devices based on the detected presence of the minimum level voltage potential on the one or more electrical conductors.

16. (canceled)

17. The device of claim 15, wherein the plurality of illumination devices are positioned at least partially within the illumination channel to provide the visible light emission viewable outside the illumination channel from at least any angle of view of the illumination channel that is perpendicular to a longitudinal axis of the illumination coupling.

18. The device of claim 15, wherein at least one of the one or more electrical circuits comprises:
a sensing capacitor having a capacitor input and a capacitor output, the capacitor input electrically coupled to one of the one or more electrical conductors or terminals received within the electrical coupler, and
a plurality of diodes coupled to the capacitor output and to a reference voltage,
wherein the sensing capacitor forms a capacitive ballast circuit between the capacitor input and the plurality of diodes, the capacitive ballast circuit configured to provide a reduced voltage output when the minimum level voltage potential is present at the capacitor input, the reduced voltage output configure to control the illumination of the plurality of illumination devices based on the detected presence of the minimum level voltage potential at the one of the one or more electrical conductors or terminals.

19-21. (canceled)

22. The device of claim 18, wherein the reduced voltage output comprises a voltage level that is directly coupled to one or more of the plurality of illumination devices to illuminate the one or more illumination devices in response to detection of the minimum level voltage potential at the capacitor input.

23. The device of claim 18, wherein the at least one of the one or more electrical circuits further comprises:
an opto-coupler configured to receive the reduced voltage output, and to provide a control voltage output based on a voltage level provided by the reduced voltage output,
a driver circuit including a control input coupled to the pair of opto-coupler outputs and a driver circuit output coupled to one or more of the plurality of illumination devices, the driver circuit configured to receive the control voltage output at the control input of the opto-coupler and to provide electrical power to the one or more illumination devices coupled to the driver circuit outputs to illuminate the one or more illumination devices in response to detection of that the voltage level at the reduced voltage output corresponds to the minimum level voltage potential is detected at the capacitor input.

24. The device of claim 23, wherein the driver circuit is configured to control the illumination of the one or more illumination devices to provide a first color of visible light when the minimum level voltage potential is detected, and to control the illumination of the one or more illumination devices to provide a second color of visible light that is different from the first color of visible light when the minimum level voltage potential is not detected.

25. The device of claim 15,
wherein the one or more electrical conductors or terminals include three power electrical conductors received within the electrical coupler, each of the three power electrical conductors configured to provide electrical power associated with one phase of a three-phase alternating current electrical configuration, and
wherein the one or more electrical circuits comprise three electrical circuits, each of the three electrical circuits electrically coupled to one and only one of the three power electrical conductors and configured to control the illumination of one or more of the plurality of illumination devices based on the sensed presence of a minimum level voltage potential at the one and only one electrical conductor.

26. The device of claim 15, further comprising:
an illumination insert located within the illumination channel and configured to cover the plurality of illumination devices, the illumination insert further configured to perform a light mixing function by mixing wavelengths of different colors of light being emitted the plurality of illumination devices in order to provide a light emission from the illumination channel having a wavelength or wavelengths comprising the mixed wavelengths of different colors of light.

27-32. (canceled)
